(19) United States
(12) Patent Application Publication
(10) Pub. No.: US 2014/0342174 A1
(43) Pub. Date: Nov. 20, 2014

(54) MIRROR FILM, METHOD FOR PRODUCING THE SAME, AND MIRROR FILM FOR SOLAR THERMAL POWER GENERATORS OR SOLAR PHOTOVOLTAIC POWER GENERATORS

(71) Applicant: FUJIFILM CORPORATION, Tokyo (JP)

(72) Inventors: Jo TOMINAGA, Kanagawa (JP); Kazuma TAKENO, Kanagawa (JP); Daisuke ARIOKA, Kanagawa (JP)

(21) Appl. No.: 14/449,153

(22) Filed: Aug. 1, 2014

Related U.S. Application Data
(63) Continuation of application No. PCT/JP2013/052906, filed on Feb. 7, 2013.

(30) Foreign Application Priority Data
Feb. 14, 2012 (JP) 2012-029957
Sep. 28, 2012 (JP) 2012-218261

(51) Int. Cl. C25D 5/56; H01L 31/052; F24J 2/46; G02B 5/08

(52) U.S. Cl. CPC C25D 5/56; G02B 5/0808; H01L 31/0525; F24J 2/4652
USPC 428/551; 205/184; 126/684

(57) ABSTRACT

A mirror film including a support, a plating undercoat polymer layer containing reduced metal particles, a reflective layer containing silver, and a resin protective layer, in this order. A surface roughness Ra of a surface of the reflective layer containing silver at a resin protective layer side is 20 nm or less.

### CROSS-REFERENCE TO RELATED APPLICATION

This application is a Continuation of PCT International Application No. PCT/JP2013/052906, filed Feb. 7, 2013, which claims priority under 35 U.S.C. §119(a) to Japanese Patent Application Nos. 2012-029957 filed Feb. 14, 2012, and 2012-218261 filed Sep. 28, 2012. Each of the above applications is hereby expressly incorporated by reference, in its entirety, into the present application.

### BACKGROUND OF THE INVENTION

1. Technical Field

The present invention relates to a mirror film, a method for producing the same, and a mirror film for solar thermal power generators or solar photovoltaic power generators.

2. Background Art

In recent years, alternative energies to fossil fuel energy as represented by petroleum energy, are being actively studied. In particular, wind power generation, geothermal power generation, solar thermal power generation, solar photovoltaic power generation, and the like are clean natural energies, and it is said that these natural energies hold the key to the development of energy in the future. Among these, since power generation utilizing solar energy is stable and the quantity of solar energy is large, it is thought that power generation utilizing solar energy should be particularly effective.

However, although solar energy is a very effective alternative energy, in terms of utilizing solar energy, it is said that there are problems in that the energy density of solar energy is low, and it is difficult to store and transfer the energy so that it is hard to utilize at night, for example, and the like.

Recently, in order to address these problems, light-concentration type solar photovoltaic power generation and light-concentration type solar thermal power generation have been proposed. These systems aim to address the problem of the low energy density of solar energy by concentrating sunlight using a reflective mirror.

However, such a reflective mirror may be exposed to ultraviolet rays or heat rays due to sunlight, wind and rain and chemical forces such as sea breeze or acidic rain, or physical forces such as dust, powdery dust, or sandstorms and, therefore, a reflective mirror made of glass has been used conventionally. However, although mirrors made of glass have high durability with respect to the environment, mirrors made of glass are characterized by being heavy and easily breakable and, therefore, there have been problems in that breakage is caused during transportation, the cost of construction runs high since it is necessary to build a strong platform to install a heavy mirror, a large amount of energy is needed for driving so as to follow the sun, and the like.

Meanwhile, as a method for addressing the above problems, it is thought that the use of a mirror made of plastic should be effective; however, since mirrors made of plastic have a low reflectance, a large number of mirrors is required, and there has been a problem in that a large installation area is needed and construction costs are high. Further, in mirrors made of plastic, the adhesion between a plastic base material and a reflective metal film is poor, and thus there is a problem with long-term outdoor use.

Examples of a method for forming a metal film on a plastic base material include, mainly, vapor deposition and plating processing. In order to enhance the adhesion by plating, a method of providing irregularities on the surface of a plastic film base material, to enhance the adhesion between a metal and the film base material by an anchoring effect, has been used. However, regarding the method of enhancing the adhesion by the anchoring effect, in a case in which the thickness of the metal film is small, there is a problem in that the irregularities of the plastic film base material remain, and thus the reflection performance may be impaired.

In connection to the above, a method of coating a polymer that can interact with an electroless plating catalyst, then adsorbing an electroless plating catalyst, and then performing electroless plating or further performing electroplating, thereby forming a metal film on a film base material with high adhesion and high smoothness, has been disclosed (see, for example, International Publication WO 2010-150570 and Japanese Patent Application Laid-Open (JP-A) No. 2009-164575).

However, in the film formation by electroless plating, a self-deposition reaction of metal can easily occur in the treatment liquid used in the electroless plating and the lifetime of the treatment liquid may be significantly shortened and, therefore, there have been problems in terms of production efficiency and costs. Further, another problem has also occurred whereby the degree of surface irregularities is increased by the electroless plating treatment, resulting in deterioration of reflectance.

Meanwhile, in connection to the above, a method of coating a metal precursor-containing polymer and then performing reduction on a metal, or coating a polymer that can interact with a metal precursor, then adsorbing a metal precursor, and then reducing the metal precursor to a metal, to form a plating undercoat polymer layer containing metal particles on a plastic film base material, thereby imparting electric conductivity, and then forming thereon a metal layer by electroplating, has been disclosed (see, for example, JP-A Nos. 2009-164575 and 2006-228478). According to these methods, electroplating can be directly performed without a stage of electroless plating, and thus there is no problem with the self-deposition of metal, and a metal film can be formed on a plastic film base material with favorable adhesion.

However, by film formation according to these methods, the surface smoothness depends on the surface irregularities of the undercoat polymer layer or the particle size of the reduced metal. Therefore, a surface which is smooth to some extent may be obtained, but a surface smoothness sufficient as a reflective mirror for concentrating sunlight cannot be obtained, and problems with low reflection performance have occurred.

### SUMMARY OF INVENTION

### Technical Problem

Usually, a plastic film base material that serves as a support has poor adhesion with respect to a metal. In order to enhance the adhesion between a metal and a plastic film base material, the following methods have been used. Namely, (1) a method of providing irregularities on the surface of a film base material to enhance the adhesion, utilizing an anchoring effect between a metal and the film base material, and (2) a method of forcibly incorporating a metal into a film base material by way of, for example, sputtering or ion injection, thereby enhancing the adhesion, and the like. However, with regard to the method of enhancing the adhesion by the anchoring effect, in a case in which the thickness of the metal film is small, the irregularities remain, and thus there is a problem in that only a mirror film in which the metal film obtained exhibits low reflection performance is obtained. Further, in order to address the above problem, a film thickness larger than or equal to the degree of irregularities of the film base material is needed, and thus, there is a problem in that the film thickness of the metal film becomes remarkably large. Further, in regard to the method of forcibly incorporating a metal into a film base material by way of, for example, sputtering or ion injection, since the method requires high energy, the productivity is low, and in view of the problems of heat generation or the like, there is a problem in that production cannot be achieved with the use of a low-cost and versatile plastic film.

The present invention has been made in view of the above circumstances, and an aspect of the invention is to provide a mirror film which has high reflection performance, has favorable adhesion between the support and the reflective layer, and can endure long-term outdoor use, and that is also lightweight and less likely to be broken.

Further, another aspect of the invention is to provide a simple method for producing a mirror film having the above performance, and yet another aspect of the invention is to provide a solar thermal power generator and solar photovoltaic power generator using the mirror film.

### Solution to Problem

Specific means for addressing the above problems are as follows.

<1> A mirror film, including, in this order: a support; a plating undercoat polymer layer containing reduced metal particles; a reflective layer containing silver; and a resin protective layer, a surface roughness Ra of a surface of the reflective layer containing silver at a resin protective layer side being 20 nm or less.

<2> The mirror film according to item <1>, wherein an average primary particle diameter of the reduced metal particles is in a range of from 1 nm to 100 nm.

<3> The mirror film according to item <1> or item <2>, wherein a surface roughness Ra of a surface of the plating undercoat polymer layer containing the reduced metal particles at a reflective layer side is 20 nm or less.

<4> The mirror film according to any one of items <1> to <3>, wherein a surface resistance value of the plating undercoat polymer layer containing the reduced metal particles is in a range of from 0.001Ω/□ to 100 Ω/□.

<5> The mirror film according to item <4>, wherein the surface resistance value of the plating undercoat polymer layer containing the reduced metal particles is in a range of from 0.03Ω/□ to 50 Ω/□.

<6> The mirror film according to any one of items <1> to <5>, wherein the plating undercoat polymer layer containing the reduced metal particles includes an acrylic polymer.

<7> The mirror film according to item <6>, wherein the acrylic polymer is an acrylic polymer having an acidic group and a polymerizable group in a side chain thereof, and forms an interaction between polymerizable groups of the acrylic polymer, or between the polymerizable groups of the acrylic polymer and the support, by applying energy, within the plating undercoat polymer layer.

<8> The mirror film according to any one of items <1> to <7>, having a light reflectance of 90% or higher at a wavelength of 600 nm.

<9> A method of producing the mirror film according to any one of items <1> to <8>, including: forming a plating undercoat polymer layer containing reduced metal particles on a support; forming a reflective layer containing silver, by electroplating; and forming a resin protective layer.

<10> The method of producing the mirror film according to item <9>, wherein the forming of a plating undercoat polymer layer containing reduced metal particles includes: forming a polymer layer containing a metal precursor on the support; and reducing the metal precursor.

<11> The method of producing the mirror film according to item <9> or item <10>, wherein the forming of a polymer layer containing a metal precursor on the support includes applying the metal precursor after imparting energy to the support having a polymer layer.

<12> The method of producing the mirror film according to any one of items <9> to <11>, wherein the polymer used to form the undercoat polymer layer is selected from the group consisting of: a copolymer including: a structural unit containing a polymerizable group and represented by the following Formula (A), a structural unit containing a first interactive group and represented by the following Formula (B), the first interactive group being a non-dissociative functional group, and a structural unit containing a second interactive group and represented by the following Formula (C), the second interactive group being an ionic polar group; a copolymer including: the structural unit represented by the following Formula (A), and the structural unit represented by the following Formula (B); and a copolymer including: the structural unit represented by the following Formula (A), and the structural unit represented by the following Formula (C):

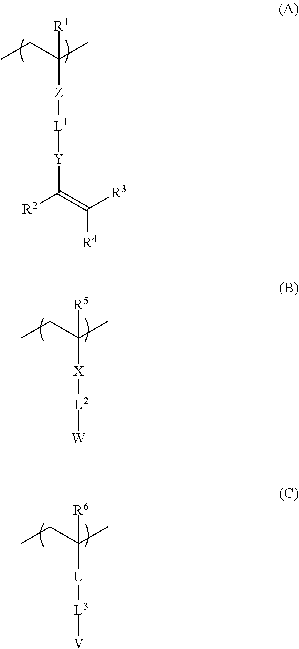

wherein, in Formulae (A) to (C), each of R1 to R6 independently represents a hydrogen atom or a substituted or unsubstituted alkyl group having from 1 to 4 carbon atoms; each of X, Y, Z, and U independently represents a single bond, a substituted or unsubstituted divalent organic group, an ester group, an amide group, or an ether group; each of L¹, L², and L³ independently represents a single bond, or a substituted or unsubstituted divalent organic group; W represents a non-dissociative functional group that forms an interaction with a plating catalyst or a precursor thereof; and V represents an ionic polar group that forms an interaction with a plating catalyst or a precursor thereof.

<13> The method of producing the mirror film according to any one of items <10> to <12>, wherein forming a plating undercoat polymer layer containing reduced metal particles on the support includes applying, on the support, a composition for forming a polymer layer, the composition including a material that generates an active species.

<14> The method of producing the mirror film according to any one of items <11> to <13>, including: removing unreacted polymer after the application of energy to the support having the undercoat polymer layer; and thereafter, reducing the metal precursor.

<15> The production method of the mirror film according to any one of items <10> to <14>, wherein reducing the metal precursor includes reducing a metal precursor by contacting the metal precursor with an aqueous solution containing a reducing agent.

<16> The production method of the mirror film according to any one of items <9> to <15>, wherein forming a reflective layer containing silver, by electroplating, includes washing the support having the undercoat polymer layer after the electroplating.

<17> A solar thermal power generator or a solar photovoltaic power generator including the mirror film according to any one of items <1> to <8>.

The mirror film of the invention is characterized in that a plating undercoat polymer layer containing reduced metal particles is provided on a support and a reflective layer containing silver is provided on the plating undercoat polymer layer, in order to obtain favorable adhesion between the film base material and the metal film that serves as a reflective layer. By disposing the plating undercoat polymer layer between the support and the reflective layer, the reflective layer containing silver exhibits excellent adhesion with respect to the film base material that serves as a support. Further, since the metal layer that serves as a reflective layer contains silver and has smoothness such that the surface roughness of the resin protective layer side surface is 20 nm or less, a mirror film having a high reflectance is obtained. The surface roughness of 20 nm or less can be realized, for example, by controlling the conditions (the exposure amount and the like) in film formation of the plating undercoat polymer layer or the reduction conditions (the alkali concentration, the kind of reducing agent, and the like) as described in the examples of this specification.

It is guessed that a high adhesion strength is exhibited, due to the interaction between the reduced metal particles contained in the plating undercoat polymer layer and the silver contained in the reflective layer, and the affinity between the polymer and reduced metal particles contained in the plating undercoat polymer layer.

Further, it is guessed that, since the reflective layer containing silver can be formed without going through electroless plating, the surface of the plating undercoat polymer layer never becomes rough due to electroless plating, so that a high reflectance is exhibited.

### Advantageous Effects of Invention

According to the invention, a mirror film which has favorable adhesion between the support and the reflective layer, can endure long-term outdoor use, as well as, is lightweight, and is less likely to be broken may be provided.

Further, according to the invention, a simple method for producing a mirror film having the above performance may be provided, and a solar thermal power generator and solar photovoltaic power generator using the mirror film may be provided.

### BRIEF DESCRIPTION OF DRAWINGS

FIG. 1 is a diagram showing the results of the weather resistance (2) test of Example 1.

FIG. 2 is a diagram showing the results of the light resistance test of Example 1.

### DESCRIPTION OF EMBODIMENTS

Hereinafter, preferable exemplary embodiments of the mirror film of the invention are described. Hereinafter, for convenience, explanation is made by attaching symbols (A) to (D) to the constituent elements in some cases.

The mirror film according to the invention is characterized in that the mirror film has (A) a support, (B) a plating undercoat polymer layer containing reduced metal particles, (C) a reflective layer (hereinafter, if appropriate, referred to as “silver-containing metal layer”.) which contains silver and has a surface roughness Ra of 20 nm or less, and (D) a resin protective layer, in this order, in which the silver-containing metal layer constitutes the reflection plane.

First, with regard to the respective layers, the components that constitute the respective layers are explained, and next, the production method is explained. In the explanation of the respective layers, the production method is also partially explained.

<(A) Support>

In the invention, as the material of the film base material used as the (A) support, for example, a resin film obtained by molding glass epoxy, polyester, polyimide, thermosetting type polyphenylene ether, polyamide, polyaramid, paper, a liquid crystal polymer, or the like into a film can be used, from the viewpoints of flexibility and weight saving.

As the resin, a phenol resin, an epoxy resin, a polyimide resin, a BT resin, a PPE resin, a tetrafluoroethylene resin, a liquid crystal resin, a polyester resin, PEN, an aramid resin, a polyamide resin, polyether sulfone, triacetyl cellulose, polyvinyl chloride, polyvinylidene chloride, polyethylene, polypropylene, polystyrene, polybutadiene, polyacetylene, and the like are preferable, and any resin that can be formed into a film can be used.

Particularly preferable examples of the support include a film of a polyester resin and a film of a polyimide resin.

The shape of the support may be any shape that is required as a film base material in various mirror films with planar face, diffusion face, concave face, convex face, or the like.

The thickness of the support is preferably from about 10 μm to about 5 mm. When the support is thinner than the above range, handling at the time of production may become difficult, and when the support is thicker than the above range, molding may become difficult. The thickness of the support is more preferably from 20 μm to 1 mm, and still more preferably from 25 μm to 500 μm.

Further, the support may be subjected to a surface treatment in advance, in order to facilitate the formation of (B) a plating undercoat polymer layer that is to be provided on the support. Examples of the surface treatment, which may be performed, include a treatment of decomposing and activating the surface, such as UV irradiation, an ozone treatment, a plasma treatment, a corona treatment, or a flame treatment; a treatment using an alkaline solution such as hydrazine, N-methylpyrrolidone, a sodium hydroxide solution, or a potassium hydroxide solution; a treatment using an acidic solution such as sulfuric acid, hydrochloric acid, or nitric acid; and a treatment of removing stains on the surface of a support using an organic solvent, such as methanol, ethanol, toluene, ethyl acetate, or acetone, to clean the surface. Further, naturally, water washing for removing adhered dusts, or the like may also be carried out. Moreover, for further forming a plating undercoat polymer layer, another undercoat layer that is different from the plating undercoat polymer layer may be provided on the support.

For the purpose of enhancing the reflection performance of the mirror film, it is preferable to use a support having a surface roughness (Ra) of 50 nm or less. It is more preferable that Ra is 20 nm or less. It is still more preferable that the average roughness (Ra) is 5 nm or less.

Further, it is preferable that the support contains at least one ultraviolet absorbent selected from ultraviolet absorbents, such as a benzotriazole-based ultraviolet absorbent, a benzophenone-based ultraviolet absorbent, a triazine-based ultraviolet absorbent, or a polymer type absorbent such as cyanoacrylate-based ultraviolet absorbent, and inorganic particle type ultraviolet absorbents such as titanium oxide.

Moreover, the support may contain a plasticizer for maintaining flexibility, an antioxidant that prevents deterioration of film itself, a radical scavenger, or the like.

(Antioxidant)

As the antioxidant, it is preferable to use a phenol-based antioxidant, a thiol-based antioxidant, or a phosphite-based antioxidant.

Examples of the phenol-based antioxidant include
1,1,3-tris(2-methyl-4-hydroxy-5-t-butylphenyl)butane,
2,2′-methylenebis(4-ethyl-6-t-butylphenol),
tetrakis[methylene-3-(3′,5′-di-t-butyl-4′-hydroxyphenyl)propionato]methane,
2,6-di-t-butyl-p-cresol, 4,4′-thiobis(3-methyl-6-t-butylphenol),
4,4′-butylidenebis(3-methyl-6-t-butylphenol),
1,3,5-tris(3′,5′-di-t-butyl-4′-hydroxybenzyl)-S-triazin-2,4,6(1H,3H,5H)-trione,
stearyl-β-(3,5-di-t-butyl-4-hydroxyphenyl)propionate, triethylene glycol bis[3-(3-t-butyl-5-methyl-4-hydroxyphenyl)propionate],
3,9-bis[1,1-di-methyl-2-[β-(3-t-butyl-4-hydroxy-5-methylphenyl)propionyloxy]ethyl]-2,4,8,1 0-tetraoxaspiro[5,5]undecane, and
1,3,5-trimethyl-2,4,6-tris(3,5-di-t-butyl-4-hydroxybenzyl)benzene.

Particularly, a phenol-based antioxidant having a molecular weight of 550 or more is preferable.

Examples of the thiol-based antioxidant include distearyl-3,3′-thiodipropionate and pentaerythritol-tetrakis(β-lauryl-thiopropionate).

Examples of the phosphite-based antioxidant include tris(2,4-di-t-butylphenyl) phosphite, distearyl pentaerythritol diphosphite, di(2,6-di-t-butylphenyl) pentaerythritol diphosphite, bis(2,6-di-t-butyl-4-methylphenyl)-pentaerythritol diphosphite, tetrakis(2,4-di-t-butylphenyl) 4,4′-biphenylene-diphosphonite, and 2,2′-methylenebis(4,6-di-t-butylphenyl)octyl phosphite.

In the case of using an antioxidant in the support, the content of the antioxidant is preferably in a range of from 0.01 parts by mass to 10 parts by mass, with respect to 100 parts by mass of the resin that constitutes the base material of the support.

(Ultraviolet Absorbent)

Examples of the ultraviolet absorbent include a benzophenone-based ultraviolet absorbent, a benzotriazole-based ultraviolet absorbent, a phenyl salicylate-based ultraviolet absorbent, a hindered amine-based ultraviolet absorbent and a triazine-based ultraviolet absorbent.

Examples of the benzophenone-based ultraviolet absorbent include 2,4-dihydroxy-benzophenone, 2-hydroxy-4-methoxy-benzophenone, 2-hydroxy-4-n-octoxy-benzophenone, 2-hydroxy-4-dodesiloxy-benzophenone, 2-hydroxy-4-octadesiloxy-benzophenone, 2,2′-dihydroxy-4-methoxy-benzophenone, 2,2′-dihydroxy-4,4′-dimethoxy-benzophenone, and 2,2′,4,4′-tetrahydroxy-benzophenone.

Examples of the benzotriazole-based ultraviolet absorbent include
2-(2′-hydroxy-5-methylphenyl)benzotriazole,
2-(2′-hydroxy-3′,5′-di-t-butylphenyl)benzotriazole, and
2-(2′-hydroxy-3′-t-butyl-5′-methylphenyl)benzotriazole.

Examples of the phenyl salicylate-based ultraviolet absorbent include phenyl salicylate and 2,4-di-t-butylphenyl-3,5-di-t-butyl-4-hydroxy benzoate. Examples of a hindered amine-based ultraviolet absorbent include bis(2,2,6,6-tetramethylpiperidin-4-yl) sebacate.

Examples of the triazine-based ultraviolet absorbent include
2,4-diphenyl-6-(2-hydroxy-4-methoxyphenyl)-1,3,5-triazine,
2,4-diphenyl-6-(2-hydroxy-4-ethoxyphenyl)-1,3,5-triazine,
2,4-diphenyl-(2-hydroxy-4-propoxyphenyl)-1,3,5-triazine,
2,4-diphenyl-(2-hydroxy-4-butoxyphenyl)-1,3,5-triazine,
2,4-diphenyl-6-(2-hydroxy-4-butoxyphenyl)-1,3,5-triazine,
2,4-diphenyl-6-(2-hydroxy-4-hexyloxyphenyl)-1,3,5-triazine,
2,4-diphenyl-6-(2-hydroxy-4-octyloxyphenyl)-1,3,5-triazine,
2,4-diphenyl-6-(2-hydroxy-4-dodecyloxyphenyl)-1,3,5-triazine, and
2,4-diphenyl-6-(2-hydroxy-4-benzyloxyphenyl)-1,3,5-triazine.

In addition to the above ultraviolet absorbents, a compound having a function of converting the energy possessed by ultraviolet light into a vibrational energy in the molecule and releasing the vibrational energy as a heat energy or the like is included as an ultraviolet absorbent. Further, a compound which expresses an effect when used in combination with an antioxidant, a coloring agent, or the like, or a light stabilizer called a quencher, which acts as a light energy conversion agent, or the like can also be used in combination.

In the case of using an ultraviolet absorbent in the support, the content of the ultraviolet absorbent is preferably in a range of from 0.01 parts by mass to 10 parts by mass with respect to 100 parts by mass of the resin that constitutes the base material of the support.

<(B) Plating Undercoat Polymer Layer Containing Reduced Metal Particles>

The (B) plating undercoat polymer layer containing reduced metal particles in the invention has at least reduced metal particles and a plating undercoat polymer described below.

In the invention, it is preferable to form the (B) plating undercoat polymer layer containing reduced metal particles according to the invention by forming a plating undercoat polymer layer containing a metal precursor on the support by way of coating or the like, using a composition containing a metal precursor and a plating undercoat polymer described below, or by forming a layer on the support using a composition containing a plating undercoat polymer described below, then forming a metal precursor-containing polymer layer by bringing a composition containing a metal precursor into contact with the above layer that has been provided on the support, and thereafter, reducing the metal precursor contained in the metal precursor-containing plating undercoat polymer layer.

(Plating Undercoat Polymer)

First, the plating undercoat polymer used in the composition for forming a plating undercoat polymer layer is explained.

The plating undercoat polymer used in the composition for forming a plating undercoat polymer layer according to the invention has at least a polymerizable group and a functional group (hereinafter, if appropriate, referred to as “interactive group”.) that interacts with a metal precursor. As described below in detail, the interactive group includes an ionic polar group, such as an acidic group, and a non-dissociative functional group such as a cyano group.

It is enough that the plating undercoat polymer has a polymerizable group and an interactive group in the molecule, and it is enough that the plating undercoat polymer has the polymerizable group at least at the terminal of the main chain of the polymer or on the side chain. Examples include a polymer containing a structural unit having a polymerizable group and a structural unit having an interactive group, and the like. Further, a polymerizable group and an interactive group may be contained in the same structural unit. Further, two or more kinds of polymerizable groups may be contained, or two or more kinds of interactive groups may be contained. Moreover, a polymerizable group may be introduced through a polymer reaction, after the preparation of the polymer.

The plating undercoat polymer may contain a structural unit other than the structural unit containing a polymerizable group or the structural unit containing an interactive group, depending on the purpose. By the inclusion of the structural unit (hereinafter, if appropriate, referred to as “additional structural unit”.) other than the structural unit containing a polymerizable group or the structural unit containing an interactive group, when preparing a composition for forming a plating undercoat polymer layer, the plating undercoat polymer exhibits excellent solubility with respect to water or an organic solvent, and a uniform plating undercoat polymer layer can be formed.

(Main Skeleton of Plating Undercoat Polymer Layer)

As the main skeleton of the plating undercoat polymer, an acrylic polymer, polyether, polyacrylamide, polyamide, polyimide, polyester, or the like is preferred, and an acrylic polymer is more preferred.

The acrylic polymer is preferably a polymer compound containing, as the interactive group, an acidic group that serves an ionic polar group on the side chain, and a polymerizable group on the side chain.

Examples of the acidic group to be introduced into the acrylic polymer include a carboxyl group, a phosphoric acid group, and a sulfonic acid group. Among them, a carboxyl group is preferable from the viewpoint of availability of raw material.

Further, preferable examples of the polymerizable group include various polymerizable groups such as a (meth)acrylate group, a (meth)acrylamido group, a vinyl carboxylate ester group, a vinyl ether group, an ally ether group, an allyl ester group, or a styryl group.

More specifically, examples of the acrylic polymer include compounds obtained by adding, to an acrylic resin containing a carboxyl group, a cyclic ether group-containing polymerizable compound or an epoxy group-containing polymerizable compound, for example, glycidyl acrylate, glycidyl methacrylate, a glycidyl ester of an unsaturated fatty acid such as sinnamic acid or the like, or a compound having an alicyclic epoxy group (for example, an epoxy group such as cyclohexene oxide in the same molecule) and a (meth)acryloyl group. Further, examples include compounds obtained by adding an isocyanato group-containing polymerizable compound such as isocyanatoethyl (meth)acrylate to an acrylic resin containing an acidic group and a hydroxyl group, and compounds obtained by adding a hydroxyl group-containing polymerizable compound such as hydroxyalkyl (meth)acrylate to an acrylic resin containing an acid anhydride group. Moreover, examples include compounds obtained by performing copolymerization using a cyclic ether group-containing polymerizable compound, such as glycidyl methacrylate, and a vinyl monomer such as (meth)acryloylalkyl ester, and then adding (meth)acrylic acid to the epoxy group on the side chain.

Examples of these compounds include compounds described in Japanese Patent No. 2763775, JP-A Nos. H3-172301 and 2000-232264, and the like.

Above all, it is more preferable that the acrylic polymer is a polymer compound selected from any of compounds obtained by adding a polymerizable compound containing a cyclic ether group (for example, a group having an epoxy group or an oxetane group as a partial structure) to some of the acidic groups of a polymer compound, and compounds obtained by adding a carboxyl group-containing polymerizable compound to some or all of the cyclic ether groups of a polymer compound.

Hereinafter, the polymerizable group and interactive group, which are contained in the plating undercoat polymer, the properties thereof, and the like are described in detail.

(Polymerizable Group)

The polymerizable group possessed by the plating undercoat polymer may be any functional group as long as it can form a chemical bond between the polymers or between the polymer and a ground layer (a support or an undercoat layer provided on a support), by the application of energy. Examples of the polymerizable group include a radical polymerizable group and a cation polymerizable group. Examples of the cation polymerizable group include functional groups including an oxetane ring, an oxirane ring (an epoxy ring), or a vinyl ether group.

Among them, from the viewpoint of reactivity, a radical polymerizable group is preferable.

The polymerizable group is not particularly limited and can be selected as appropriate according to the purpose but, for example, polymerizable groups represented by any one of the following Formula (A-5) to (A-7) are preferable.

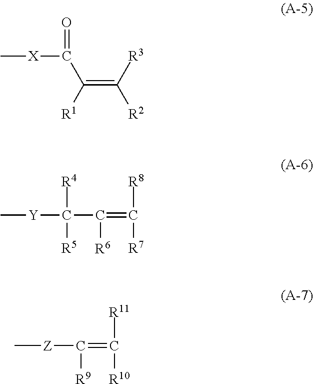

In Formula (A-5) to (A-7), each of R¹ to R¹¹ independently represents a hydrogen atom or a monovalent organic group. Each of X and Y independently represents an oxygen atom, a sulfur atom, or —N(—R¹²)—. Z represents an oxygen atom, a sulfur atom, —N(—R¹³)—, or a phenylene group. Each of R¹² and R¹³ independently represents a hydrogen atom or a monovalent organic group.

In Formula (A-5) above, R¹ preferably represents, for example, a hydrogen atom, an alkyl group which may have a substituent, or the like, and more preferably represents a hydrogen atom or a methyl group, because of having high radical reactivity.

Examples of R² and R³ each independently include a hydrogen atom, a halogen atom, an amino group, a carboxyl group, an alkoxycarbonyl group, a sulfo group, a nitro group, a cyano group, an alkyl group which may have a substituent, an aryl group which may have a substituent, an alkoxy group which may have a substituent, an aryloxy group which may have a substituent, an alkylamino group which may have a substituent, an arylamino group which may have a substituent, an alkylsulfonyl group which may have a substituent, and an arylsulfonyl group which may have a substituent. Among them, a hydrogen atom, a carboxyl group, an alkoxycarbonyl group, an alkyl group which may have a substituent, and an aryl group which may have a substituent are more preferable, because of having high radical reactivity.

R¹² in —N(—R¹²)— represented by X above preferably represents, for example, a hydrogen atom, an alkyl group which may have a substituent, or the like, and more preferably represents a hydrogen atom, a methyl group, an ethyl group, or an isopropryl group, because of having high radical reactivity.

Examples of the substituent capable of being introduced into these groups include an alkyl group, an alkenyl group, an alkynyl group, an aryl group, an alkoxy group, an aryloxy group, a halogen atom, an amino group, an alkylamino group, an arylamino group, a carboxyl group, an alkoxycarbonyl group, a sulfo group, a nitro group, a cyano group, an amido group, an alkylsulfonyl group, and an arylsulfonyl group.

In Formula (A-6) above, R⁴ to R⁸ preferably represents, for example, a hydrogen atom, a halogen atom, an amino group, a dialkylamino group, a carboxyl group, an alkoxycarbonyl group, a sulfo group, a nitro group, a cyano group, an alkyl group which may have a substituent, an aryl group which may have a substituent, an alkoxy group which may have a substituent, an aryloxy group which may have a substituent, an alkylamino group which may have a substituent, an arylamino group which may have a substituent, an alkylsulfonyl group which may have a substituent, an arylsulfonyl group which may have a substituent, or the like, and more preferably represents a hydrogen atom, a carboxyl group, an alkoxycarbonyl group, an alkyl group which may have a substituent, or an aryl group which may have a substituent.

Examples of the substituent capable of being introduced into these groups include the same as those exemplified as the substituent capable of being introduced into R¹, R², or R¹² in Formula (A-5) above.

Examples of R¹² in —N(—R¹²)— represented by Y above include the same as those exemplified as R¹² in Formula (A-5) above.

In Formula (A-7) above, R⁹ preferably represent, for example, a hydrogen atom, an alkyl group which may have a substituent, or the like, and more preferably represents a hydrogen atom or a methyl group, because of having high radical reactivity.

Further, R¹⁰ and R¹¹ each preferably represents, for example, a hydrogen atom, a halogen atom, an amino group, a dialkylamino group, a carboxyl group, an alkoxycarbonyl group, a sulfo group, a nitro group, a cyano group, an alkyl group which may have a substituent, an aryl group which may have a substituent, an alkoxy group which may have a substituent, an aryloxy group which may have a substituent, an alkylamino group which may have a substituent, an arylamino group which may have a substituent, an alkylsulfonyl group which may have a substituent, an arylsulfonyl group which may have a substituent, or the like. Among them, a hydrogen atom, a carboxyl group, an alkoxycarbonyl group, an alkyl group which may have a substituent, and an aryl group which may have a substituent are more preferable, because of having high radical reactivity.

Here, examples of the substituent capable of being introduced include the same as those exemplified as the substituent capable of being introduced into R¹, R², or R¹² in Formula (A-5) above.

Z represents an oxygen atom, a sulfur atom, —NR¹³—, or a phenylene group which may have a substituent. R¹³ represents a hydrogen atom or an alkyl group which may have a substituent, and more preferably represents a hydrogen atom, a methyl group, an ethyl group, or an isopropyl group, because of having high radical reactivity.

Among the polymerizable groups represented by Formula (A-5) to (A-7) above, the polymerizable groups represented by Formula (A-5) are more preferable, in terms of high polymerization reactivity and high sensitivity.

The content of the polymerizable group in the plating undercoat polymer is not particularly limited, but is preferably from 0.1 meq/g to 3.0 meq/g, more preferably from 0.3 meq/g to 3.0 meq/g, and particularly preferably from 0.5 meq/g to 2.5 meq/g. When the content is within this range, the reaction amount may be further increased, and excellent resistance to a treatment liquid of an alkali liquid may be exhibited.

Here, the content (meq/g) can be measured, for example, by iodine value titration.

The method of introducing the polymerizable group represented by Formula (A-5) above into a side chain of a plating undercoat polymer is not particularly limited but, for example, a plating undercoat polymer having the polymerizable group represented by Formula (A-5) on the side chain can be obtained by allowing a polymer compound containing a carboxyl group on the side chain to undergo an addition reaction with a compound having a polymerizable group and an epoxy group.

A polymer compound having a carboxyl group on the side chain can be produced, for example, by an ordinary radical polymerization method using one or more kinds of radical polymerizable compounds containing a carboxyl group and, if necessary, as a copolymerization component, one or more kinds of other radical polymerizable compounds. Examples of the radical polymerization method include a suspension polymerization method and a solution polymerization method.

The compound having a polymerizable group and an epoxy group is not particularly limited as long as the compound has these groups but, for example, a compound represented by the following Formula (A-8) and a compound represented by the following Formula (A-9) are preferable.

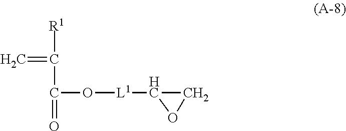

In Formula (A-8) above, R¹ represents a hydrogen atom or a methyl group. L¹ represents a divalent organic group.

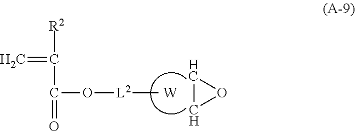

In Formula (A-9) above, R² represents a hydrogen atom or a methyl group. L² represents a divalent organic group. W represents an atomic group necessary for forming a 5-membered to 10-membered aliphatic hydrocarbon ring together with two CHs.

Among the compounds represented by Formula (A-8) above and the compounds represented by Formula (A-9) above, the compounds represented by Formula (A-8) are preferable, and among the compounds represented by Formula (A-8) above, compounds in which L¹ represents an alkylene group having from 1 to 4 carbon atoms are more preferable.

The compound represented by Formula (A-8) above and the compound represented by Formula (A-9) are not particularly limited. Examples include the following exemplary compounds (31) to (40).

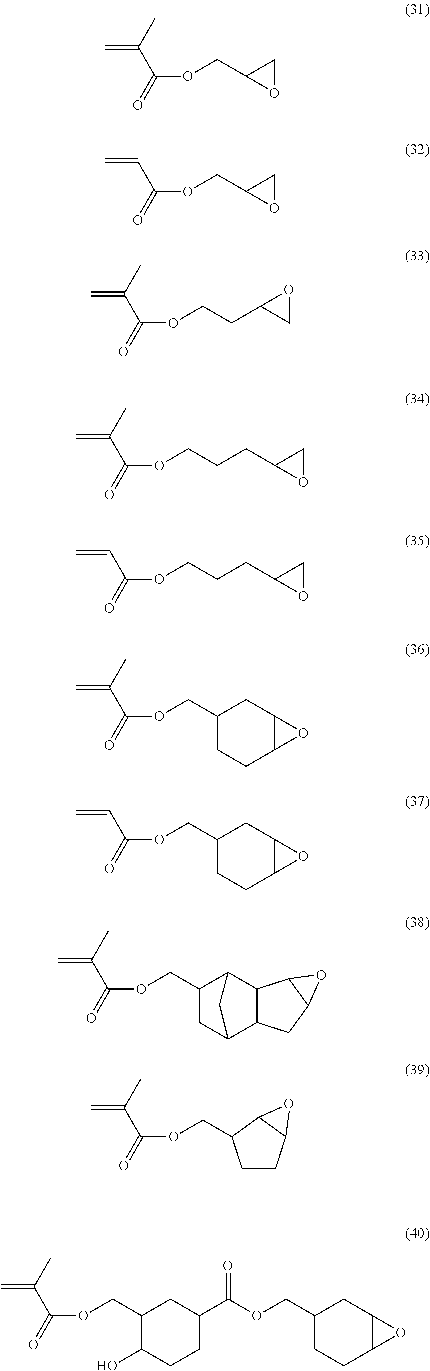

Examples of the radical polymerizable compound containing a carboxyl group include acrylic acid, methacrylic acid, itaconic acid, crotonic acid, isocrotonic acid, maleic acid, and p-carboxystyrene. Particularly preferable examples include acrylic acid and methacrylic acid.

As to the reaction for introduction into the side chain, introduction can be carried out by allowing to react at a reaction temperature of from 50° C. to 150° C. for several hours to several tens hours in an organic solvent, using, as a catalyst, for example, a tertiary amine such as triethylamine or benzylmethylamine, a quaternary ammonium salt such as dodecyltrimethylammonium chloride, tetramethylammonium chloride, or tetraethylammonium chloride, pyridine, triphenylphosphine, or the like.

The structural unit having a polymerizable group on the side chain is not particularly limited but, for example, a structural unit represented by the following Formula (A-10), a structural unit represented by the following Formula (A-11), and a structural unit represented by a mixture thereof are preferable.

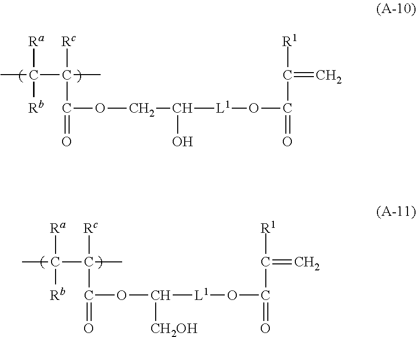

In Formula (A-10) and Formula (A-11) above, each of R^{a} to R^{c} independently represents a hydrogen atom and a monovalent organic group. R¹ represents a hydrogen atom or a methyl group. L¹ represents a divalent organic group.

The content of the structural unit represented by Formula (A-10) above and/or the structural unit represented by Formula (A-11) in the plating undercoat polymer is preferably 2 mol % or more, more preferably from 2 mol % to 50 mol %, and particularly preferably from 5 mol % to 45 mol %. When the content is within this range, favorable treatment liquid resistance to an alkali liquid may be exhibited, and also, more favorable storage stability may be exhibited.

(Interactive Group)

The interactive group possessed by the plating undercoat polymer is a functional group (for example, a coordinating group, a metal ion adsorbing group, or the like) that interacts with a metal precursor. As the interactive group, a functional group capable of forming a static interaction with a metal precursor, or a nitrogen-containing functional group, sulfur-containing functional group, or oxygen-containing functional group, which can form coordination with a metal precursor, or the like can be used.

The interactive group may be a non-dissociative functional group or may be an ionic polar group, or these groups may be incorporated simultaneously.

More specifically, examples of the interactive group include a nitrogen-containing functional group such as an amino group, an amido group, an imido group, a urea group, a tertiary amino group, an ammonium group, an amidino group, a triazine group, a triazole group, a benzotriazole group, an imidazole group, a benzimidazole group, a quinoline group, a pyridine group, a pyrimidine group, a pyrazine group, a nazoline group, a quinoxaline group, a purine group, a triazine group, a piperidine group, a piperazine group, a pyrrolidine group, a pyrazole group, an aniline group, a group containing an alkylamine structure, a group containing an isocyanuric structure, a nitro group, a nitroso group, an azo group, a diazo group, an azido group, a cyano group, or a cyanato group (R—O—CN); an oxygen-containing functional group such as an ether group, a hydroxyl group, a phenolic hydroxyl group, a carboxyl group, a carbonate group, a carbonyl group, an ester group, a group containing an N-oxide structure, a group containing an S-oxide structure, or a group containing an N-hydroxy structure; a sulfur-containing functional group such as a thiophene group, a thiol group, a thiourea group, a thiocyanuric acid group, a benzothiazole group, a mercaptotriazine group, a thioether group, a thioxy group, a sulfoxide group, a sulfo group, a sulfite group, a group containing a sulfoxyimine structure, a group containing a sulfoxinium salt structure, or a group containing a sulfonic acid ester structure; a phosphorus-containing functional group such as a phosphote group, a phosphoramido group, a phosphine group, or a group containing a phosphoric ester structure; and a group containing a halogen atom such as chlorine or bromine. In the functional groups capable of forming a salt structure, salts of these functional groups can also be used.

(Interactive Group Composed of Non-Dissociative Functional Group)

As the interactive group that is composed of a non-dissociative functional group, among the above interactive groups, an ether group and a cyano group are particularly preferable, and a cyano group is most preferable, because of having high polarity and high adsorption ability to a plating catalyst or the like.

In general, as the polarity gets higher, the water absorption rate tends to get higher. However, since cyano groups interact with each other so as to cancel the polarity of each other in the plating undercoat polymer layer, the film becomes dense and the polarity of the plating undercoat polymer layer as a whole decreases, whereby water absorbing property gets lower, despite having high polarity. Further, when a plating catalyst is adsorbed using a good solvent of the plating undercoat polymer layer, the cyano groups are solvated and interaction between the cyano groups is canceled, thereby enabling the cyano groups to interact with the plating catalyst. From the reasons described above, the plating undercoat polymer layer having a cyano group is preferable, in view of achieving both of contradictory properties of low moisture absorption and favorable interaction with the plating catalyst.

Further, among the above described substituents, the interactive group in the invention is more preferably a cyano group or an alkylcyano group. The reason for this is as follows. In an aromatic cyano group, electrons are attracted to the aromatic ring, and thus the donating property of unpaired electrons that play an important role for the adsorption property with respect to a plating catalyst or the like may be decreased. However, in an alkylcyano group, such an aromatic ring is not bonded thereto. Therefore, an alkylcyano group is preferable in terms of the adsorption property with respect to a plating catalyst or the like.

(Interactive Group Composed of Ionic Polar Group)

As the interactive group that is composed of an ionic polar group, among the above interactive groups, an acidic group is preferable, from the viewpoint of adhesion to the base material of the plating undercoat polymer. More specifically, examples include a carboxylic acid group, a sulfonic acid group, a phosphoric acid group, and a boric acid group. Among them, a carboxylic acid group is particularly preferable, from the viewpoint of having appropriate acidity (such that decomposition of other functional group does not occur) and from the viewpoint of improvement in various performance such as improvement in affinity with the plated layer.

A carboxylic acid group can be applied to the plating undercoat polymer through performing copolymerization using a radical polymerizable compound having a carboxylic acid group.

The radical polymerizable compound having a carboxylic acid group is not particularly limited, and can be selected as appropriate depending on the purpose. Examples thereof include acrylic acid, methacrylic acid, itaconic acid, crotonic acid, isocrotonic acid, maleic acid, and p-carboxystyrene. Among them, acylic acid, methacrylic acid, and p-carboxystyrene are preferable. These compounds may be used singly or in combination of two or more kinds thereof.

The content of the carboxylic acid group in the plating undercoat polymer is from 1.0 meq/g to 12.0 meq/g, preferably from 2.0 meq/g to 9.0 meq/g, and more preferably from 2.5 meq/g to 8.0 meq/g. When the content is within this range, the affinity with the plated layer may be sufficient, and it is possible to further reduce the damage on the plated surface caused by the post treatment using alkali water or the like.

Hereinafter, preferable constitutions of the plating undercoat polymer used in the invention are described in detail.

(Unit Constitution of Plating Undercoat Polymer)

The plating undercoat polymer according to the invention has, as described above, a polymerizable group and an interactive group that forms interaction with a plating catalyst or a precursor thereof, wherein the interactive group may be a non-dissociative functional group or an ionic polar group. The plating undercoat polymer is a polymer that contains at least one of a non-dissociative functional group or an ionic polar group.

Preferable embodiments of the plating undercoat polymer include a copolymer including a unit that contains a polymerizable group and is represented by the following Formula (A), a unit that contains an interactive group composed of a non-dissociative functional group and is represented by the following Formula (B), and a unit that contains an interactive group composed of an ionic polar group and is represented by the following Formula (C); a copolymer including a unit represented by the following Formula (A) and a unit represented by the following Formula (B); and a copolymer including a unit represented by the following Formula (A) and a unit represented by the following Formula (C).

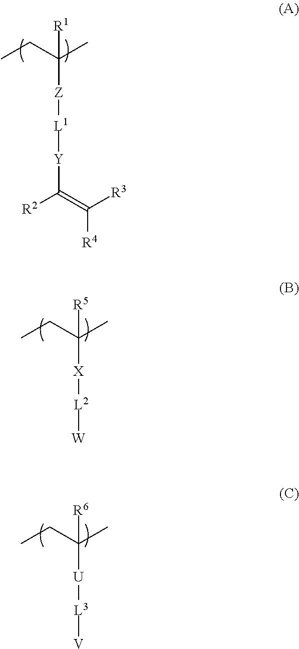

In Formulae (A) to (C) above, each of R¹ to R⁶ independently represents a hydrogen atom or a substituted or unsubstituted alkyl group having from 1 to 4 carbon atoms; each of X, Y, Z, and U independently represents a single bond, a substituted or unsubstituted divalent organic group (which may have a linking group), an ester group, an amido group, or an ether group; each of L¹, L², and L³ independently represents a single bond, or a substituted or unsubstituted divalent organic group (which may have a linking group); W represents a non-dissociative functional group that forms interaction with a plating catalyst or a precursor thereof; and V represents an ionic polar group that forms interaction with a plating catalyst or a precursor thereof.

The term “organic group” used in the invention refers to a substituent containing a carbon atom.

In the unit represented by Formula (A), it is preferable that each of Y and Z independently represents an ester group, an amido group, or a phenylene group (—C₆H₄—). L¹ preferably represents a substituted or unsubstituted divalent organic group having from 1 to 10 carbon atoms.

In the unit represented by Formula (B), it is preferable that W represents a cyano group or an ether group. Further, it is preferable that each of X and L² represents a single bond.

Further, in the unit represented by Formula (C), it is preferable that V represents a carboxylic acid group. In a preferable embodiment, V represents a carboxylic acid group and the part where L³ links with V includes a 4-membered to 8-membered cyclic structure. Further, in another preferable embodiment, V represents a carboxylic acid group and the length of the chain L³ is from 6 atoms to 18 atoms. Specific examples of such a polymer include polymers described in [Chemical Formula 10] and [Chemical Formula 14] of JP-A Nos. 2010-248464.

Moreover, in the unit represented by Formula (C), in one of preferable embodiments, V represents a carboxylic acid group, and U and L³ represent a single bond. Above all, in the most preferable embodiment, V represents a carboxylic acid group, and both U and L³ represent a single bond.

In the plating undercoat polymer in the invention, it is preferable that the proportion of the unit containing a polymerizable group (the unit represented by Formula (A)), the unit containing a first interactive group composed of a non-dissociative functional group (the unit represented by Formula (B)), and the unit containing a second interactive group composed of an ionic polar group (the unit represented by Formula (C)), with respect to the whole copolymerization unit is within the following range. The following range of mol % is selected as appropriate such that the whole thereof becomes 100 mol %.

Namely, in the case of a copolymer containing a unit represented by Formula (A), a unit represented by Formula (B), and a unit represented by Formula (C), it is preferable that the unit represented by Formula (A): the unit represented by Formula (B): the unit represented by Formula (C)=5 mol % to 50 mol %: 5 mol % to 40 mol %: 20 mol % to 70 mol %, and it is more preferable that the proportion is 10 mol % to 40 mol %: 10 mol % to 35 mol %: 20 mol % to 60 mol %.

In the case of a copolymer containing a unit represented by Formula (A) and a unit represented by Formula (B), it is preferable that the unit represented by Formula (A): the unit represented by Formula (B)=5 mol % to 50 mol %: 50 mol % to 95 mol %, and it is more preferable that the proportion is 10 mol % to 40 mol %: 60 mol % to 90 mol %.

Further, in the case of a copolymer containing a unit represented by Formula (A) and a unit represented by Formula (C), it is preferable that the unit represented by Formula (A): the unit represented by Formula (C)=5 mol % to 50 mol %: 50 mol % to 95 mol %, and it is more preferable that the proportion is 10 mol % to 40 mol %: 60 mol % to 90 mol %.

When the proportion is within this range, improvement in polymerizability of the plating undercoat polymer with respect to UV exposure, lowering of resistance value of the plating undercoat polymer containing reduced metal particles after the reduction of the metal precursor, and improvement in humidity-proof adhesion strength can be realized.

The plating undercoat polymer is preferably obtained by copolymerization further using, other than the above radical polymerizable compound, an additional radical polymerizable compound, for the purpose of improving various performance such as image strength or the like.

Examples of the additional radical polymerizable compound include radical polymerizable compounds selected from the group consisting of (meth)acrylic acid esters such as alkyl (meth)acrylate or aryl (meth)acrylate, styrenes such as styrene, alkylstyrene, alkoxystyrene, or halogenated styrene, alkyl (meth)acrylamides, vinyl ethers, N-substituted maleimides, vinylcyano compounds, and the like.

With regard to the alkyl (meth)acrylate, an alkyl (meth)acrylate in which the alkyl group has from 1 to 20 carbon atoms is preferred, and examples include (meth)acrylic acid esters containing an alkyl group having from 1 to 25 carbon atoms, such as methyl (meth)acrylate, ethyl (meth)acrylate, propyl (meth)acrylate, butyl (meth)acrylate, i-butyl (meth)acrylate, t-butyl (meth)acrylate, amyl (meth)acrylate, hexyl (meth)acrylate, ethylhexyl (meth)acrylate, octyl (meth)acrylate, t-octyl (meth)acrylate, i-octyl (meth)acrylate, i-decyl (meth)acrylate, lauryl (meth)acrylate, chloroethyl (meth)acrylate, 2,2-dimethylhydroxypropyl (meth)acrylate, 5-hydroxypentyl (meth)acrylate, trimethylolpropane mono(meth)acrylate, pentaerythritol mono(meth)acrylate, glycidyl (meth)acrylate, benzyl (meth)acrylate, methoxybenzyl (meth)acrylate, cyanoethyl (meth)acrylate, cyanopropyl (meth)acrylate, cyanobenzyl (meth)acrylate, furfuryl (meth)acrylate, or tetrahydrofurfuryl (meth)acrylate. Among them, (meth)acrylic acid esters containing an alkyl group having from 2 to 15 carbon atoms are preferable, and acrylic acid esters are more preferable.

Examples of the aryl (meth)acrylate include aryl (meth)acrylates containing an alkyl group having from 1 to 25 carbon atoms, such as phenyl (meth)acrylate, cresyl (meth)acrylate, or naphthyl (meth)acrylate. Among them, phenyl acrylate is preferable.

Examples of the styrenes include styrenes having from 1 to 25 carbon atoms, such as methylstyrene, dimethylstyrene, trimethylstyrene, ethylstyrene, diethylstyrene, isopropylstyrene, butylstyrene, hexylstyrene, cyclohexylstyrene, decylstyrene, benzylstyrene, chloromethylstyrene, trifluoromethylstyrene, ethoxymethylstyrene, acetoxymethylstyrene, cyanostyrene, or the like; alkoxystyrenes such as methoxystyrene, 4-methoxy-3-methylstyrene, or dimethoxystyrene; or halogenated styrenes such as chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethylstyrene, or 4-fluoro-3-trifluoromethylstyrene. Above all, styrene and methoxystyrene are preferable.

Examples of the alkyl (meth)acrylamides include (meth)acrylamides containing an alkyl group having from 1 to 22 carbon atoms, such as methyl (meth)acrylamide, dimethyl (meth)acrylamide, diethyl (meth)acrylamide, dibutyl (meth)acrylamide, t-butyl (meth)acrylamide, octyl (meth)acrylamide, or dodecyl (meth)acrylamide. Above all, acrylamide and isopropylacrylamide are preferable.

Examples of the vinyl ethers include methyl vinyl ether, ethyl vinyl ether, propyl vinyl ether, n-butyl vinyl ether, t-butyl vinyl ether, 2-ethylhexyl vinyl ether, n-nonyl vinyl ether, lauryl vinyl ether, cyclohexyl vinyl ether, cyclohexylmethyl vinyl ether, 4-methyl cyclohexylmethyl vinyl ether, benzyl vinyl ether, dicyclopentenyl vinyl ether, 2-dicyclopentenoxyethyl vinyl ether, methoxyethyl vinyl ether, ethoxyethyl vinyl ether, butoxyethyl vinyl ether, methoxyethoxyethyl vinyl ether, ethoxyethoxyethyl vinyl ether, methoxypolyethylene glycol vinyl ether, tetrahydrofurfuryl vinyl ether, 2-hydroxyethyl vinyl ether, 2-hydroxypropyl vinyl ether, 4-hydroxybutyl vinyl ether, 4-hydroxymethyl cyclohexylmethyl vinyl ether, diethylene glycol monovinyl ether, polyethylene glycol vinyl ether, chloroethyl vinyl ether, chlorobutyl vinyl ether, chloroethoxyethyl vinyl ether, phenylethyl vinyl ether, and phenoxypolyethylene glycol vinyl ether. Above all, phenyl vinyl ether and butyl vinyl ether are preferable.

Examples of the N-substituted maleimides include N-methylmaleimide, N-ethylmaleimide, N-n-propylmaleimide, N-i-propylmaleimide, N-n-butylmaleimide, N-t-butylmaleimide, N-n-hexylmaleimide, N-cyclopentylmaleimide, N-cyclohexylmaleimide, N-phenylmaleimide, and N-1-naphthylmaleimide. Among them, N-cyclohexylmaleimide and N-phenylmaleimide are preferable, and N-phenylmaleimide is more preferable.

Examples of the vinylcyano compounds include (meth)acrylonitrile, cyanopropene, and dicyanoethylene.

These additional radical polymerizable compounds may be used singly as an additional radical polymerizable compound, or in combination of two or more kinds thereof.

In the invention, the solvent used in synthesizing the plating undercoat polymer is not particularly limited, and can be selected as appropriate depending on the purpose. Examples of the solvent include ethylene dichloride, cyclohexanone, methyl ethyl ketone, acetone, methanol, ethanol, propanol, butanol, ethylene glycol monomethyl ether, ethylene glycol monoethyl ether, 2-methoxyethyl acetate, 1-methoxy-2-propanol, 1-methoxy-2-propyl acetate, N,N-dimethylformamide, N,N-dimethylacetamide, dimethylsulfoxide, toluene, ethyl acetate, methyl lactate, and ethyl lactate. These solvents may be used singly or in mixture of two or more kinds thereof.

Further, in the invention, the plating undercoat polymer may include an unreacted monomer. In this case, the content of the unreacted monomer in the plating undercoat polymer is preferably 15% by mass or less.

In the invention, the plating undercoat polymers may be used singly or in mixture of two or more kinds thereof. Further, an additional polymer compound having a structure different from that of the plating undercoat polymer may be mixed and used. In this case, the content of the additional polymer compound in the plating undercoat polymer is preferably 50% by mass or less, and more preferably 30% by mass or less.

The weight average molecular weight of the plating undercoat polymer in the invention is preferably from 1,000 to 700,000, more preferably from 2,000 to 200,000, and still more preferably from 5,000 to 100,000. When the weight average molecular weight is within this range, a higher adhesion strength may be obtained, and also, resistance to a treatment liquid such as alkali water may be obtained, and more favorable storability over time may be exhibited.

Note that, the weight average molecular weight described herein is a value measured by using GPC (used solvent: N-methylpyrrolidone) and determined as a polystyrene-equivalent molecular weight. For example, the weight average molecular weight can be measured under the following conditions.
Column: guard column TOSOH TSK GUARDCOLUMN SUPER AW-H (trade name)
   separation column TOSOH TSK GEL SUPER AWM-H (trade name) (three columns with a size of 6.0 mm×15 cm are connected)
Eluent: N-methylpyrrolidone (including 10 mM of LiBr)
Flow rate: 0.35 mL/min
Detection method: RI
Temperature: column 40° C., inlet 40° C., RI 40° C.
Sample concentration: 0.1% by weight
Injection quantity: 60 μL,

Further, regarding the degree of polymerization of the plating undercoat polymer in the invention, it is preferable to use a polymer of 10-mer or more, and it is more preferable to use a polymer of 20-mer or more. Furthermore, it is preferable to use a polymer of 1,500-mer or less, and it is more preferable to use a polymer of 1,000-mer or less.

As specific examples of the plating undercoat polymer, polymers described in paragraphs [0106] to [0112] of JP-A No. 2009-007540 can be used as the polymer having a radical polymerizable group and an interactive group composed of a non-dissociative functional group. Further, as the polymer having a radical polymerizable group and an interactive group composed of an ionic polar group, polymers described in paragraphs [0065] to [0070] of JP-A No. 2006-135271, and the like can be used. As the polymer having a radical polymerizable group, an interactive group composed of a non-dissociative functional group, and an interactive group composed of an ionic polar group, polymers described in paragraphs [0010] to [0128] of JP-A No. 2010-248464, JP-A No. 2010-84196, and paragraphs [0030] to [0108] of U.S. Patent Application Publication No. 2010-080964, and the like can be used.

Hereinafter, examples of the plating undercoat polymer, which may be particularly preferably used in the invention, are shown below; however, the invention is not limited to these examples. The subscript number represents the composition ratio (mole ratio). The weight average molecular weights of the following exemplified compounds are within a range of from 10,000 to 70,000.

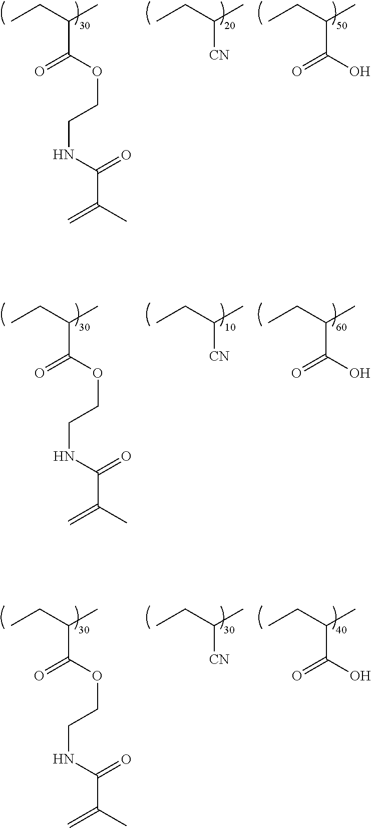

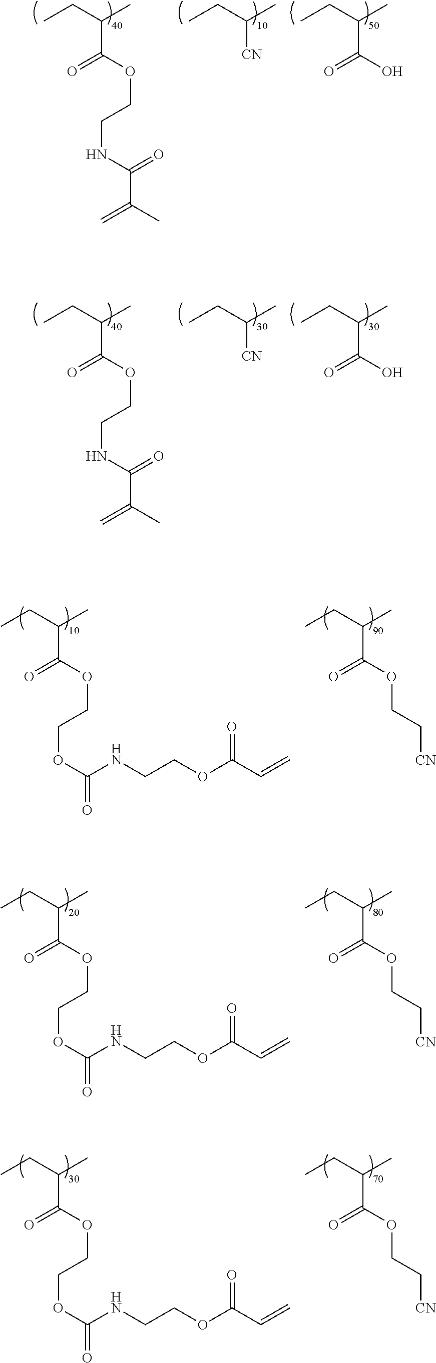

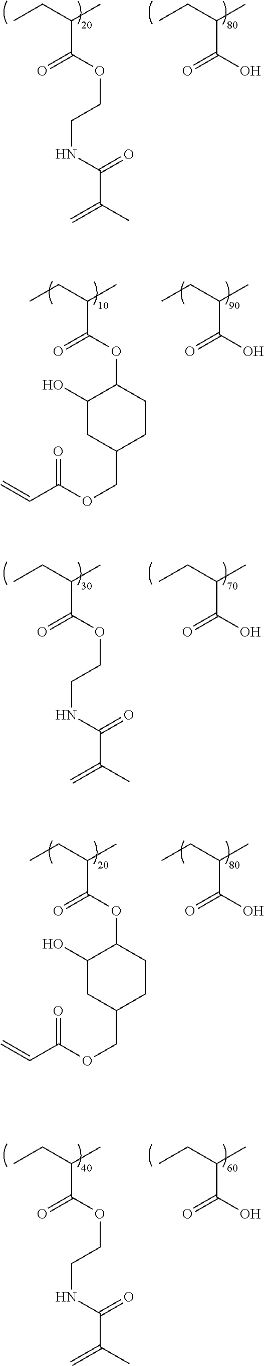

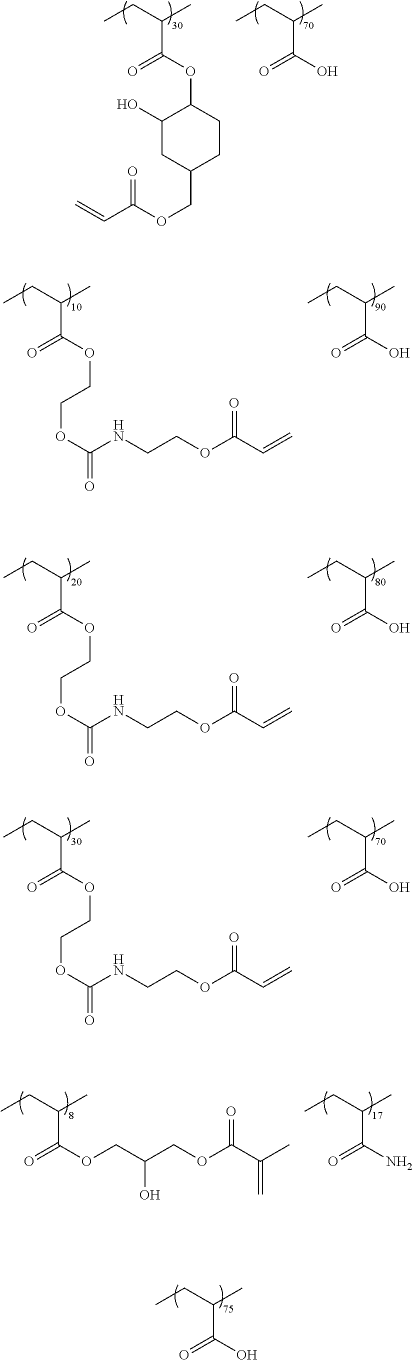

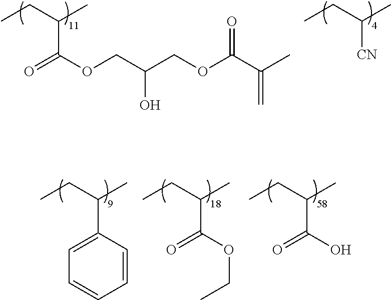

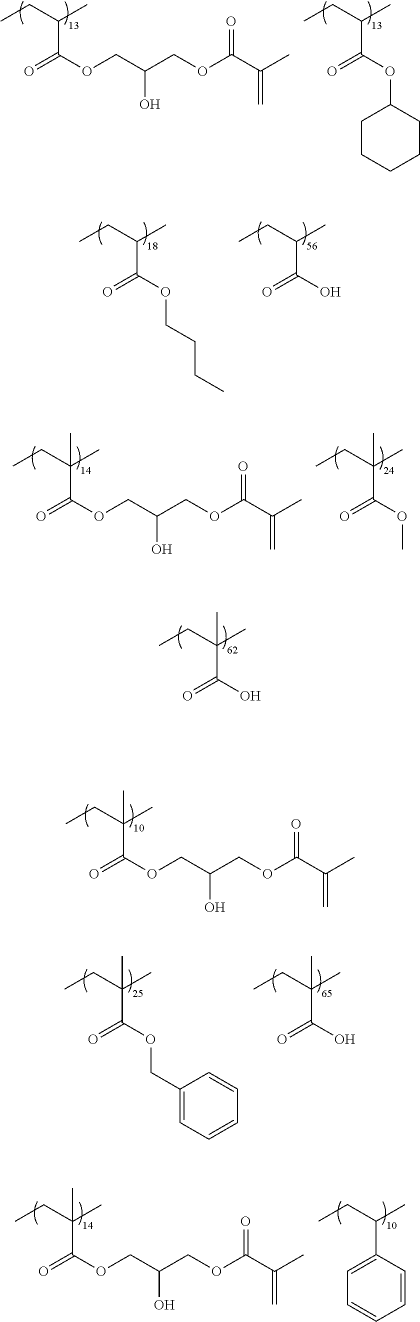

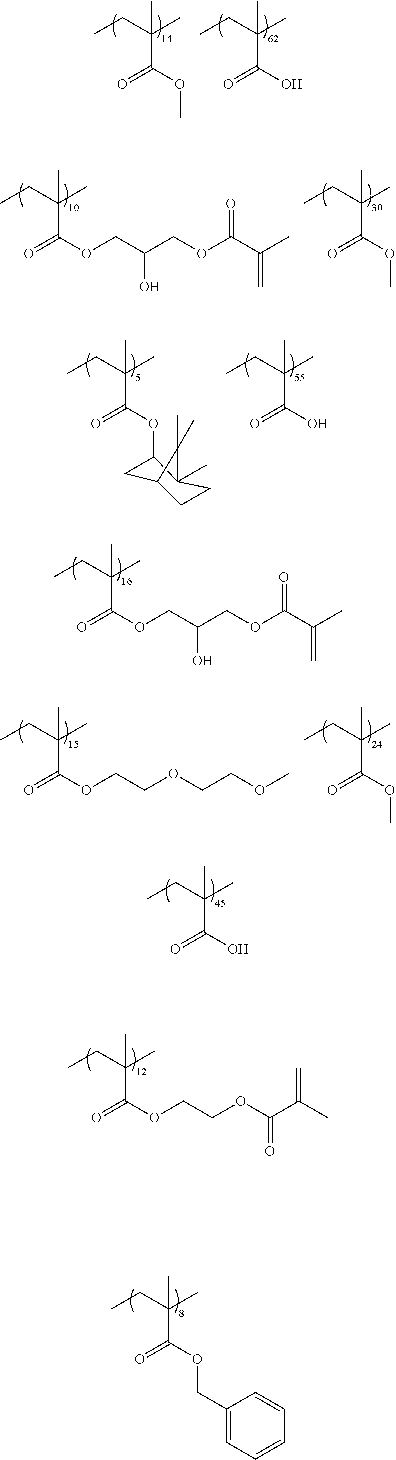

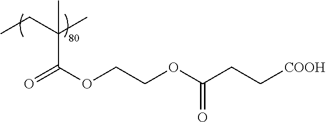

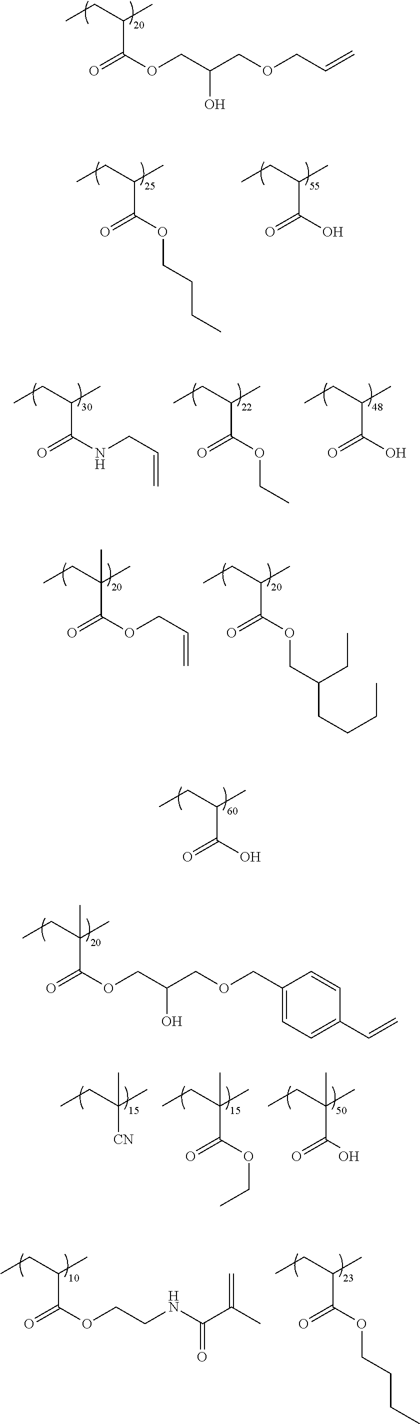

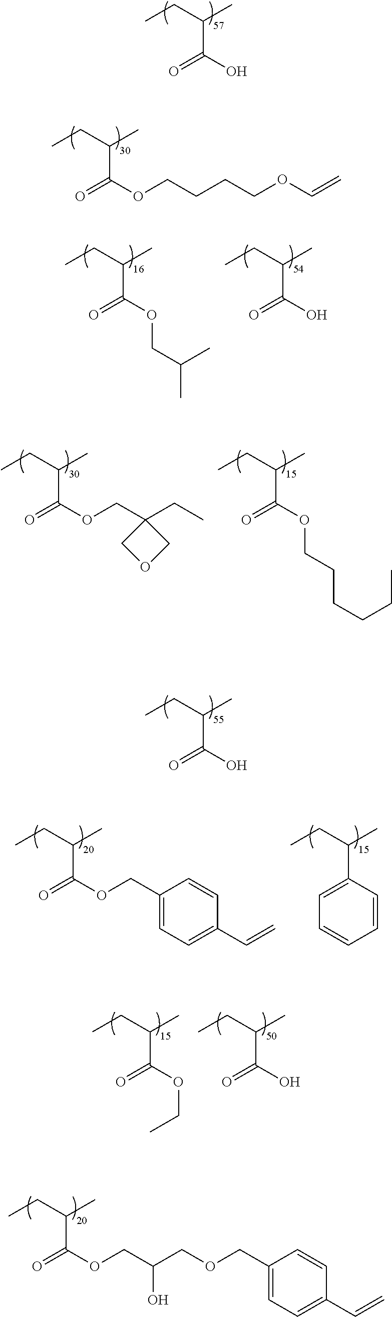

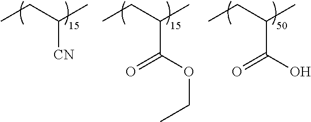

In order to form a plating undercoat polymer layer, a composition for forming a plating undercoat polymer layer may be brought into contact with a support or a support having an undercoat layer, followed by applying energy. The contact of a composition for forming a plating undercoat polymer layer with a support is preferably carried out by coating a coating liquid containing the composition for forming a plating undercoat polymer layer on the support.

(Composition for Forming Plating Undercoat Polymer Layer)

The composition for forming a plating undercoat polymer layer contains a plating undercoat polymer.

The content of the plating undercoat polymer in the composition for forming a plating undercoat polymer layer is not particularly limited, but is preferably from 2% by mass to 50% by mass, and more preferably from 5% by mass to 30% by mass, with respect to the total amount of the composition. When the content is within the above range, the composition may have excellent handling property, and the layer thickness of the polymer layer may easily be controlled.

Further, when the content of the plating undercoat polymer is within this range, the surface state of the coated film may become more favorable, the coating liquid does not become high-viscous, and it is easier to obtain a desired coated film thickness.

Note that, the metal precursor described below may be added after the formation of the plating undercoat polymer layer, or may be contained in the composition for forming a plating undercoat polymer layer from the beginning. In the case of adding a metal precursor in the composition for forming a plating undercoat polymer layer, the content of the metal precursor is preferably from 0.5% by mass to 90% by mass, and more preferably from 1% by mass to 50% by mass, with respect to the total amount of the composition. When the content is within this range, in the case of using the plating undercoat polymer layer containing reduced metal particles as an electrode, the electric conductivity is favorable and the loss of energy is small.

[Solvent]

It is preferable that the composition for forming the plating undercoat polymer layer according to the invention contains, other than the plating undercoat polymer described above, a solvent capable of dissolving this plating undercoat polymer.

The solvent which can be used in the composition for forming the plating undercoat polymer layer is not particularly limited, and solvents that are used for ordinary coating or the like can be used. Examples include alcohol solvents such as methanol, ethanol, propanol, ethylene glycol, glycerin, or 1-methoxy-2-propanol; acids such as acetic acid; ketone solvents such as acetone, methyl ethyl ketone, or cyclohexanone; amide solvents such as formamide, dimethylacetamide, or N-methylpyrrolidone; nitrile solvents such as acetonitrile or propionitrile; ester solvents such as methyl acetate or ethyl acetate; carbonate solvents such as dimethyl carbonate or diethyl carbonate; and further, ether solvents, glycol solvents, amine solvents, thiol solvents, halogen solvents, and the like. These solvents may be used singly or may be used as a mixture.

The content of the solvent in the composition for forming a plating undercoat polymer layer is not particularly limited, but is preferably from 50% by mass to 95% by mass, and more preferably from 70% by mass to 90% by mass, with respect to the total amount of the composition. When the content is within the above range, the composition may have excellent handling property and the film thickness of the plating undercoat polymer layer may be controlled easily.

In the composition for forming a plating undercoat polymer layer according to the invention, by neutralizing the ionic polar group using a base to enhance the hydrophilicity, water can also be used as the solvent. Considering the coating property at the time of coating, it is preferable to use water and a water-soluble organic solvent in combination as the solvent. In this case, the content of the organic solvent is preferably from 20% by mass to 90% by mass, with respect to the whole solvent. The term “water-soluble organic solvent” used herein means an organic solvent which is soluble in water within the above range of content. As far as the organic solvent has such a nature, any organic solvent can be used as the solvent of the composition without any particular limitation. As the water-soluble organic solvent, for example, a ketone solvent, an ester solvent, an alcohol solvent, an ether solvent, an amine solvent, a thiol solvent, a halogen solvent, or the like is preferably used.

Hereinafter, specific examples of the organic solvent suitable for use in the invention are described.

Examples of the ketone solvent include 4-hydroxy-4-methyl-2-pentanone, γ-butyrolactone, and hydroxyacetone. Examples of the ester solvent include 2-(2-ethoxyethoxy)ethyl acetate, ethylene glycol monomethyl ether acetate, diethylene glycol monoethyl ether acetate, methyl cellosolve acetate, 2-hydroxyethyl acrylate, hydroxypropyl acrylate, methyl glycolate, and ethyl glycolate.

Examples of the alcohol solvent include methanol, ethanol, isopropyl alcohol, normal propyl alcohol, 3-acetyl-1-propanol, 2-(allyloxy)ethanol, 2-aminoethanol, 2-amino-2-methyl-1-propanol, (S)-(+)-2-amino-1-propanol, (S)-(−)-2-amino-1-propanol, 3-amino-1-propanol, 2-dimethylaminoethanol, 2,3-epoxy-1-propanol, ethylene glycol, 2-fluoroethanol, diacetone alcohol, 2-methylcyclohexanol, 4-hydroxy-4-methyl-2-pentanone, glycerin, 2,2′,2″-nitrilotriethanol, 2-pyridinemethanol, 2,2,3,3-tetrafluoro-1-propanol, 2-(2-aminoethoxy)ethanol, 2-[2-(benzyloxy)ethoxy]ethanol, 2,3-butanediol, 2-butoxyethanol, 2,2′-thiodiethanol, 1,3-butanediol, 1,4-butanediol, 2,3-butanediol, 2-methyl-2,4-pentanediol, 1,3-propanedoil, diglycerin, 2,2′-methyliminodiethanol, and 1,2-pentanediol.

Examples of the ether solvent include bis(2-ethoxyethyl)ether, bis[2-(2-hydroxyethoxy)ethyl]ether, 1,2-bis(2-methoxyethoxy) ethane, bis[2-(2-methoxyethoxy)ethyl]ether, bis(2-methoxyethyl)ether, 2-(2-butoxyethoxy)ethanol, 2-[2-(2-chloroethoxy)ethoxy]ethanol, 2-ethoxyethanol, 2-(2-ethoxyethoxy)ethanol, 2-isobutoxyethanol, 2-(2-isobutoxyethoxy)ethanol, 2-isopropoxyethanol, 2-[2-(2-methoxyethoxy)ethoxy]ethanol, 2-(2-methoxyethoxy)ethanol, 1-ethoxy-2-propanol, 1-methoxy-2-propanol, tripropylene glycol monomethyl ether, methoxyacetic acid, and 2-methoxyethanol.

Examples of the glycol solvent include diethylene glycol, triethylene glycol, ethylene glycol, hexaethylene glycol, propylene glycol, dipropylene glycol, and tripropylene glycol.

Examples of the amine solvent include N-methyl-2-pyrrolidone and N,N-dimethylformamide.

Examples of the thiol solvent include mercaptoacetic acid and 2-mercaptoethanol.

Examples of the halogen solvent include 3-bromobenzyl alcohol, 2-chloroethanol, and 3-chloro-1,2-propanediol.

Other than the above solvents, solvents described in the following Tables 1 and 2 can also be used as the water-soluble organic solvent.

TABLE 1

| Acrylic acid | 2-(Dimethylamino)ethyl | Acetyl methyl carbinol |
|---|---|---|
| | acrylate | |
| 1-Amino-4-methylpiperazine | 3-Aldehyde pyridine | Isobutyric acid |
| Aluminum ethylacetoacetate diisopropylate | | Ethylene glycol |
| (water-soluble) | | |
| Ethylene glycol monobutyl ether | Ethylene chlorohydrin | N-Ethylmorpholine |
| Ethylenediamine | 3-Ethoxypropylamine | Formic acid |
| | | (86% or higher) |
| Isoamyl formate | Acetic acid | 1,4-Diaminobutane |
| 1,2-Diaminopropane | 1,3-Diaminopropane | 3-Diethylaminopropylamine |
| N,N-Diethylethanolamine | Cyclohexylamine | N,N-Dimethylacetamide |
| Di-n-butoxy-bis(triethanolaminato)titanium | | Dimethylaminopropylamine |
| 2-(Dimethylamino)acetaldehyde dimethyl acetal | | N,N-Dimethylethanolamine |
| 2,5-Dimethylpyrazine | Pyrethrum | Hydrazine hydrate |
| | (for stored grains) | (79% or lower) |
| | (emulsion) | |
| Sodium alcoholate (liquid) | Tetramethyl-1,3- | Sodium methoxide |
| | diaminopropane | |
| 1,1,3-Trihydrotetrafluoropropanol | Ethyl lactate | Methyl lactate |
| α-Picoline | β-Picoline | γ-Picoline |
| Hydrazine (79% or lower) | Propionic acid | Propylene chlorohydrin |
| Benzylaminopurine | Trimethyl borate | Methylaminopropylamine |
| (3% emulsion) | | |
| N-Methylpiperazine | 2-Methylpyrazine | 3-Methoxypropylamine |
| 2-Mercaptoethanol | Morpholine | Diethylenetriamine |

TABLE 2

| N,N-Dimethylacrylamide | Dimethylaminopropyl | Dimethylsulfoxide |
|---|---|---|
| | methacrylamide | |
| N,N-Dimethylaminopropyl acrylamide | | (−)-D-Diisopropyl tartrate |
| Hydrazine hydrate | Sulfolane | Thioglycolic acid |
| (80% or higher) | (anhydride thereof is solid | |
| | and non-hazardous) | |
| Thiodiglycol | Tetraethylenepentamine | n-Tetradecane |
| N,N,N′,N′-Tetramethyl-1,6-hexamethylenediamine | | Triethyl phosphate (TEP) |
| Triethylene glycol | Triethylenetetramine | Trimethyl phosphate |
| d-Valerolactone | Bis(aminopropyl)piperazine | Hydrazine (80% or higher) |
| 2-Hydroxyethyl acrylate | 2-Hydroxyethyl | Hydroxyethyl piperazine |
| | aminopropylamine | |
| 4-Hydroxy-2-butane | Vinyltris(β-methoxyethoxy) | 2-Pyridinemethanol |
| | silane | |
| 3-Pyridinemethanol | 4-Pyridinemethanol | Pyruvic acid |
| Phenethylamine | Formamide | 1,3-Butanediol |
| 1,4-Butanediol | Butyldiglycol | γ-Butyrolactone |
| Furfuryl alcohol | Hexylene glycol | Benzylamine |
| Pentaethylenehexamine | Polyethylene glycol diglycidyl ether | |
| | (n is about 13 or less) | |
| Polypropylene glycol diglycidyl ether | | Methacrylic acid |
| (n is about 11 or less) | | |
| 2-Hydroxyethyl methacrylate | Methyliminobispropylamine | N-Methylethanolamine |
| N-Methyl-N,N-diethanolamine | 3-Methyl-3-methoxybutyl | β-Mercaptopropionic acid |
| | acetate | |
| Ethylene glycol monoacetate | | |

From the viewpoint of the ease of evapotranspiration, the boiling point of the water-soluble organic solvent in the invention is preferably from 70° C. to 150° C., and more preferably from 65° C. to 120° C. Preferable examples of such a water-soluble organic solvent include ethanol (boiling point: 78° C.), isopropyl alcohol (boiling point: 82° C.), n-propyl alcohol (boiling point: 97° C.), THF (tetrahydrofuran, boiling point: 66° C.), 1-methoxy-2-propanol (boiling point: 119° C.), and MEK (methyl ethyl ketone, boiling point: 80° C.).

Further, as described above, in the case of using a mixed liquid of water and a water-soluble organic solvent, the flash point of the mixed liquid is preferably 30° C. or higher, more preferably 40° C. or higher, and still more preferably 60° C. or higher, from the viewpoint of ease of handling.

Note that, the term “flash point” used in the invention means a measured value obtained by a tag closed cup method in accordance with JIS-K2265.

—Water—

It is preferable that the water used in the composition for forming a plating undercoat polymer layer according to the invention is free from impurities. RO water, deionized water, distilled water, purified water, or the like is preferable, and deionized water or distilled water is more preferable.

—Additive for Enhancing Solubility of Plating Undercoat Polymer—

In the case of using a mixed liquid of water and a water-soluble organic solvent in the composition for forming a plating undercoat polymer layer according to the invention, an additive may be used in order to enhance the solubility of the plating undercoat polymer.

For example, in a case in which the plating undercoat polymer that serves as a solute has an acidic group such as a carboxylic acid group, by converting the acidic group to a salt such as sodium carboxylate, this plating undercoat polymer becomes easier to be dissolved in the mixed liquid of water and a water-soluble organic solvent. As the additive used for converting the carboxylic acid group into a salt such as sodium carboxylate, a basic compound can be used. Specifically, sodium hydrogencarbonate, sodium carbonate, sodium hydroxide, tetramethylammonium hydroxide, potassium hydrogencarbonate, potassium carbonate, potassium hydroxide, lithium hydrogencarbonate, lithium carbonate, lithium hydroxide, methylamine, dimethylamine, trimethylamine, ethylamine, diethylamine, triethylamine, butylamine, dibutylamine, tributylamine, ammonia, DBU, DBN, or the like can be used. Particularly, sodium hydrogencarbonate, sodium carbonate, and sodium hydroxide are preferable, from the viewpoints of the degree of water solubilization and optimal basicity.

[Material Capable of Generating Active Species]

In order to enhance the sensitivity with respect to energy application, it is preferable that the composition for forming a plating undercoat polymer layer according to the invention contains a material capable of generating active species. As the material capable of generating active species, various kinds of radical initiators are preferable.

As the radical initiator, a thermal polymerization initiator, a photopolymerization initiator, or the like is used. As the thermal polymerization initiator, a peroxide initiator or an azo initiator, such as benzoyl peroxide or azoisobutyronitrile, or the like can be used.

Further, as the photopolymerization initiator, either of a low molecular weight compound or a high molecular weight compound may be used, and a generally known photopolymerization initiator is used.

Examples of the low molecular weight photopolymerization initiator, which can be used, include known photopolymerization initiators such as acetophenones such as p-tert-butyltrichloroacetophenone, 2,2′-diethoxyacetophenone, or 2-hydroxy-2-methyl-1-phenylpropan-1-one; phosphine oxides such as 2,4,6-trimethylbenzoyl-diphenyl-phosphine oxide; benzophenones such as benzophenone or 4,4′-bis(dimethylamino)benzophenone; benzyl ketals such as benzyl dimethyl ketal or hydroxycyclohexyl phenyl ketone; Michler's ketone; benzoyl benzoate; benzoins such as benzoin, benzoin methyl ether, benzoin isopropyl ether, or benzoin isobutyl ether; thioxanthones such as 2-chlorothioxanthone, 2-methylthioxanthone, 2-ethylthioxanthone, or 2-isopropylthioxanthone; and other compounds (α-acyloxim ester, tetramethylthiuram monosulfide, trichloromethyltriazine, and the like). Further, a sulfonium salt, an iodonium salt, or the like, which are usually used as a photoacid generating agent, may be also used in the invention, since these compounds function as a radical generating agent when irradiated with light.

As the high molecular weight photopolymerization initiator, a polymer compound having an activated carbonyl group on the side chain, as described in JP-A Nos. H9-77891 and H10-45927, or a polymer having a polymerization initiating group on the side chain as a pendant group, as described in JP-A No. 2004-161995 can also be used by mixing with the plating undercoat polymer. This polymer is, specifically, a polymer having a functional group (polymerization initiating group) having polymerization initiating ability and a crosslinking group on the side chain, and by the use of this polymer, a form in which a polymerization initiating group is bonded to a polymer chain and the polymer chain is fixed through a crosslinking reaction can be formed. Specific examples include substances described in paragraphs [0011] to [0158] of JP-A No. 2004-161995. Further, a polymer compound having, in the skeleton thereof, the above-described low molecular weight photopolymerization initiator may also be used.

These radical initiators may be used singly or may be used as a mixture.

In a case in which the plating undercoat polymer is capable of generating an active site that interacts with a support or a support having an undercoat layer by the application of energy, namely, in the case of using a polymer having a polymerization initiating moiety in the skeleton of the plating undercoat polymer described above, these active species need not to be added.

Further, the material capable of generating these active species may be added to the resin film that forms the support or the undercoat layer on the support. In this case, not only the interaction between the plating undercoat polymers, but also the interaction between the plating undercoat polymer and the support are more favorably formed, so that the bond between the reflective layer containing silver and the support becomes stronger. Note that, as described above, in a case in which the resin that forms the support is a resin that has a polymerization initiating moiety in the polymer skeleton, the addition of the material capable of generating active species is not always needed.

The amount of the polymerization initiator contained in the composition for forming a plating undercoat polymer layer may be selected according to the constitution of the composition for forming a plating undercoat polymer layer but, generally, the content of the polymerization initiator in the composition for forming a plating undercoat polymer layer is preferably from about 0.05% by mass to about 30% by mass, and more preferably from about 0.1% by mass to about 10.0% by mass.

Further, in a case in which the polymerization initiator is contained in a resin film base material that constitutes the support, the content of the polymerization initiator is preferably from about 0.05% by mass to about 30% by mass, and more preferably from about 0.1% by mass to about 10.0% by mass, with respect to the solids in the resin film base material.

[Sensitizer]

In a case in which application of energy is performed by exposure, the composition for forming a plating undercoat polymer layer according to the invention may include a sensitizer, in addition to the radical generating agent, for the purpose of further enhancing the sensitivity with respect to the exposure.

The sensitizer is excited when exposed to actinic energy ray, and interacts with a radical generating agent (for example, energy transfer, electron transfer, or the like). Thus, it is possible to accelerate the generation of a radical.

The sensitizer usable in the invention is not particularly limited, and can be selected as appropriate from known sensitizers, depending on the exposure wavelength.

Specific examples include known polynuclear aromatic compounds (for example, pyrene, perylene, or triphenylene), xanthenes (for example, fluorescein, eosin, erythrosine, Rhodamine B, or rose bengal), cyanines (for example, indocarbocyanine, thiacarbocyanine, or oxacarbocyanine), merocyanines (for example, merocyanine or carbomerocyanine), thiazines (for example, thionine, methylene blue, or toluidine blue), acridines (for example, acridine orange, chloroflavin, or acriflavine), anthraquinones (for example, anthraquinone), squarium compounds (for example, squarium), acridones (for example, acridone, chloroacridone, N-methylacridone, N-butylacridone, N-butyl-chloroacridone, or the like), and coumarins (examples include 3-(2-benzofuroyl)-7-diethylaminocoumarin, 3-(2-benzofuroyl)-7-(1-pyrrolidinyl)coumarin, 3-benzoyl-7-diethylaminocoumarin, 3-(2-methoxybenzoyl)-7-diethylaminocoumarin, 3-(4-dimethylaminobenzoyl)-7-diethylaminocoumarin, 3,3′-carbonylbis(5,7-di-n-propoxycoumarin), 3,3′-carbonylbis(7-diethylaminocoumarin), 3-benzoyl-7-methoxycoumarin, 3-(2-furoyl)-7-diethylaminocoumarin, 3-(4-diethylaminocinnamoyl)-7-diethylaminocoumarin, 7-methoxy-3-(3-pyridylcarbonyl)coumarin, 3-benzoyl-5,7-dipropoxycoumarin, and the like, and in addition, examples include coumarin compounds described in JP-A Nos. H5-19475, H7-271028, 2002-363206, 2002-363207, 2002-363208, and 2002-363209, and the like). Further, other than the above, examples include n-butylamine, triethylamine, tri-n-butylphosphine, thioxanthone derivatives, and the like.

Examples of the combination of a radical generating agent and a sensitizer include combinations such as those of an electron transfer type initiation system [(1) an electron donation type initiator and a sensitizer, (2) an electron acceptance type initiator and a sensitizer, and (3) an electron donation type initiator, a sensitizer, and an electron acceptance type initiator (ternary initiation system)] described in JP-A No. 2001-305734.

Other than the above, a sensitizer having a basic nucleus, a sensitizer having an acidic nucleus, a sensitizer having a fluorescent brightening agent, or the like can also be used as the sensitizer.

It is preferable that the sensitizer is contained in the composition for forming a plating undercoat polymer layer according to the invention in an amount of from about 1% by mass to about 30% by mass, with respect to the mass of the plating undercoat polymer.

[Surfactant]

The composition for forming a plating undercoat polymer layer according to the invention may include a surfactant.

The surfactant used in the invention may be any surfactant as long as the surfactant is soluble in the above-described solvent. Examples of such a surfactant include anionic surfactants such as sodium n-dodecylbenzenesulfonate, cationic surfactants such as n-dodecytrimethylammonium chloride, and nonionic surfactants such as polyoxyethylene nonyl phenol ether (commercially available products include, for example, EMULGEN 910 (trade name) manufactured by Kao Corporation, and the like), polyoxyethylene sorbitan monolaurate (commercially available products include, for example, TWEEN 20 (trade name) and the like), or polyoxyethylene lauryl ether.

[Plasticizer]

Further, a plasticizer may be added to the composition for forming a plating undercoat polymer layer according to the invention, if necessary. As a usable plasticizer, a generally used plasticizer may be used, and an ester of phthalic acid (dimethyl ester, diethyl ester, dibutyl ester, di-2-ethylhexyl ester, di-normal-octyl ester, diisononyl ester, dinonyl ester, diisodecyl ester, or butyl benzyl ester), an ester of adipic acid (dioctyl ester or diisononyl ester), dioctyl azelate, an ester of sebacic acid (dibutyl ester or dioctyl ester), tricresyl phosphate, tributyl acetylcitrate, epoxidized soybean oil, trioctyl trimellitate, chlorinated paraffin, or a high boiling point solvent such as dimethyl acetamide or N-methylpyrrolidone may also be used.

[Polymerization Inhibitor]

A polymerization inhibitor may be added to the composition for forming a plating undercoat polymer layer according to the invention, if necessary. Examples of the polymerization initiator, which may be used, include hydroquinones such as hydroquinone, di-tert-butylhydroquinone, or 2,5-bis(1,1,3,3-tetramethylbutyl)hydroquinone; phenols such as p-methoxyphenol or phenol; benzoquinones; free radicals such as TEMPO (2,2,6,6-tetramethyl-1-piperidinyl-1-oxy) free radical or 4-hydroxy TEMPO free radical; phenothiazines; nitrosoamines such as N-nitrosophenylhydroxyamine or an aluminum salt thereof; and cathecols.

[Curing Agent and Curing Accelerator]

Further, as described below, in the case of forming a plating undercoat polymer layer on an adhesion auxiliary layer by using the composition for forming a plating undercoat polymer layer according to the invention, a curing agent and/or a curing accelerator may be added to the composition for forming a plating undercoat polymer layer, so as to allow curing of the adhesion auxiliary layer to proceed. For example, in a case in which an epoxy compound is contained in the adhesion auxiliary layer, examples of the curing agent and/or curing accelerator include, as polyaddition type, aliphatic polyamine, alicyclic polyamine, aromatic polyamine, polyamide, acid anhydride, phenol, phenol novolac, polymercaptan, a compound having two or more active hydrogen atoms, and the like; and as catalyst type, aliphatic tertiary amine, aromatic tertiary amine, an imidazole compound, a Lewis acid complex, and the like.

Further, examples of the curing agent and/or curing accelerator that initiates curing due to heat, light, moisture, pressure, acid, base, or the like include diethylenetriamine, triethylenetetramine, tetraethylenepentamine, diethylaminopropylamine, polyamidoamine, menthenediamine, isophoronediamine, N-aminoethylpiperazine, 3,9-bis(3-aminopropyl)-2,4,8,10-tetraoxaspiro[5,5]undecane adduct, bis(4-amino-3-methylcyclohexyl)methane, bis(4-aminocyclohexyl)methane, m-xylenediamine, diaminodiphenylmethane, m-phenylenediamine, diaminodiphenylsulfone, dicyandiamide, adipic acid dihydrazide, phthalic anhydride, tetrahydrophthalic anhydride, hexahydrophthalic anhydride, methyltetrahydrophthalic anhydride, methylhexahydrophthalic anhydride, methylnadic anhydride, dodecylsuccinic anhydride, chlorendic anhydride, pyromellitic anhydride, benzophenone tetracarboxylic acid anhydride, ethylene glycol bis(anhydrotrimate), methylcyclohexene tetracarboxylic acid anhydride, trimellitic anhydride, polyazelaic acid anhydride, phenol novolac, xylene novolac, Bisphenol A novolac, triphenylmethane novolac, biphenyl novolac, dicyclopentadiene phenol novolac, terpene phenol novolac, polymercaptan, polysulfide, 2,4-6,-tris(dimethylaminomethyl)phenol, a 2,4,6,-tris(dimethylaminomethyl)phenol-tri-2-ethylhexanoic acid salt, benzyldimethylamine, 2-(dimethylaminomethyl)phenol, 2-methylimidazole, 2-ethyl-4-methylimidazole, 2-undecylimidazole, 2-heptadecylimidazole, 2-phenylimidazole, 1-benzyl-2-methylimidazole, 1-cyanoethyl-2-methylimidazole, 2,4-diamino-6-(2-methylimidazolyl-(1))-ethyl S-triazine, a BF₃ monoethylamine complex, a Lewis acid complex, an organic acid hydrazide, diaminomaleonitrile, a melamine derivative, an imidazole derivative, a polyamine salt, an amineimide compound, an aromatic diazonium salt, a diaryl iodonium salt, a triaryl sulfonium salt, a triaryl selenium salt, and a ketimine compound.

The above curing agent and/or curing accelerator is preferably added in an amount of from about 0% by mass to about 50% by mass of the amount of the non-volatile component remaining after the solvent has been removed, from the viewpoints of the coating property of the composition for forming a plating undercoat polymer layer, adhesion to the substrate or the plated film, and the like.

Further, the curing agent and/or curing accelerator may also be added to the adhesion auxiliary layer. In this case, it is preferable that the total of the amount of the curing agent and/or curing accelerator added to the adhesion auxiliary layer and the amount of the curing agent and/or curing accelerator added to the composition for forming a plating undercoat polymer layer satisfies the above range.

[Additional Additives]

To the composition for forming a plating undercoat polymer layer according to the invention, a rubber component (for example, CTBN), a flame retardant (for example, a phosphorus-based flame retardant), a diluent, a thixotropic agent, a pigment, an antifoaming agent, a leveling agent, a coupling agent, a water-soluble substance (for example, a mineral component such as calcium oxide or magnesium oxide), a soluble, low molecular weight substance (for example, polyalkyl glycol such as ε-caprolactam or polyethylene glycol), or the like may further be added. Further, antioxidants such as those exemplified above in the paragraph of support may be added.

When a composition obtained by appropriately mixing a plating undercoat polymer and various additives is used as the composition for forming a plating undercoat polymer layer according to the invention, the physical properties of the formed plating undercoat polymer layer, for example, the coefficient of thermal expansion, glass transition temperature, Young's modulus, Poisson's ratio, rupture stress, yield stress, thermal degradation temperature, and the like, can be set up optimally. Particularly, in regard to the rupture stress, yield stress, and thermal degradation temperature, higher values are more preferable.

[Method of Forming Plating Undercoat Polymer Layer]

Hereinafter, the materials of the mirror film and the method of forming a plating undercoat polymer layer using the same are simply explained. The method for producing the mirror film is described below in detail.

(Contact of Composition for Forming Plating Undercoat Polymer Layer with Support)

The method of bringing the obtained composition for forming a plating undercoat polymer layer into contact with the film base material that forms the support is not particularly limited, and examples thereof include a method (dip coat) of dipping the film base material into the composition for forming a plating undercoat polymer layer, and a method of coating the composition for forming a plating undercoat polymer layer on the support. The method of coating the composition on the support is preferable, because the thickness of the plating undercoat polymer layer to be obtained is easily controlled.

The coating method is not particularly limited, and as a specific method, a known method such as a coating method using a double roll coater, a slit coater, an air knife coater, a wire bar coater, a slide hopper, spray coating, a blade coater, a doctor coater, a squeeze coater, a reverse roll coater, a transfer roll coater, an extrusion coater, a curtain coater, a die coater, or a gravure roll, an extrusion coating method, or a roll coating method can be used.

Further, the polymer layer may be formed by vapor deposition, or the polymer layer may be formed by ink jetting. In the case of ink jetting, the polymer layer forming region can be controlled, so that masking in the exposure becomes unnecessary.

In a case of contacting the composition for forming a plating undercoat polymer layer with the support, the application amount is preferably from 0.05 g/m² to 10 g/m², and particularly preferably from 0.3 g/m² to 5 g/m², in terms of the solid content, from the viewpoint of achieving a sufficient interaction forming property with the metal precursor described below.

In forming the plating undercoat polymer layer in the process, the drying condition is preferably such that the polymer layer is dried at a temperature of from 20° C. to 60° C. for 0 hours to 2 hours and then dried at a temperature of 60° C. or higher for 0 hours to 2 hours, and more preferably such that the polymer layer is dried at a temperature of from 20° C. to 60° C. for 1 second to 20 minutes and then dried at a temperature of 60° C. or higher for 0 hours to 2 hours.

(Application of Energy)

After the composition for forming a plating undercoat polymer layer is contacted with the support, energy is applied, and thereby, interaction between the polymerizable groups possessed by the polymer or between the polymerizable group possessed by the polymer and the support is formed in the energy applied region, to form a plating undercoat polymer layer that is fixed onto the support.

Regarding the energy application method in the process, for example, irradiation of radiation such as exposure can be used. For example, it is possible to perform light irradiation by using a UV lamp, visible ray, or the like.

Examples of the light source, which may be used for the exposure, include a mercury lamp, a metal halide lamp, a xenon lamp, and a chemical lamp. Examples of radiation include electron beams, X rays, ion beams, and far infrared rays. Further, g-line, i-line, deep-UV light, and high density energy beams (laser beams) are also applicable.

Moreover, plasma irradiation using arc discharge, glow discharge, or the like can also be used as the method for applying energy.

From the viewpoints of facilitating the progress of polymerization and suppressing the decomposition of polymer, or from the viewpoint of allowing the polymer to form favorable interaction, the exposure power is preferably in a range of from 10 mJ/cm² to 8,000 mJ/cm², and more preferably in a range of from 100 mJ/cm² to 3,000 mJ/cm².

Further, irradiation may be conducted in an atmosphere in which the oxygen concentration is suppressed to 600 ppm or less, preferably 400 ppm or less, by carrying out substitution with inert gas such as nitrogen, helium, or carbon dioxide.

In the process, since the plating formation region becomes the reflective layer formation region of the mirror film as described below, when pattern exposure is performed, the reflective layer is formed only at the exposed region. Examples of the pattern exposure include a method of scanning exposure and a method of subjecting the unexposed area to masking, by using a photo-mask.

(Removal of Unreacted Plating Undercoat Polymer)

Further, after the application of energy, if appropriate, a process of removing the unreacted polymer may be conducted. An example of a removal method is a method using a solvent. For example, the unreacted polymer can be removed by bringing the support having the plating undercoat polymer layer formed thereon into contact with a solvent that dissolves the polymer or, in the case of an alkali soluble polymer, an alkali-based developing liquid (sodium carbonate, sodium hydrogencarbonate, aqueous ammonia, or an aqueous solution of sodium hydroxide) or the like.

(Physical Properties of Plating Undercoat Polymer Layer)

The thickness of the plating undercoat polymer layer formed as described above is not particularly limited but, from the viewpoint of adhesion to the metal film that is formed afterwards as the reflective layer, the thickness is preferably from 0.05 μm to 10 μm, and more preferably from 0.3 μm to 5 μm.

Further, the dry weight is preferably from 0.05 g/m² to 10 g/m², and particularly preferably from 0.3 g/m² to 5 g/m².

The surface roughness Ra of the reflective layer side surface of the plating undercoat polymer layer containing reduced metal particles is preferably 20 nm or less, more preferably 10 nm or less, and still more preferably 5 nm or less. When the surface roughness is within this range, the Ag surface after plating becomes smooth, and the reflectivity becomes favorable.

Regarding the method of measuring the surface roughness, measurement is carried out using an atomic force microscope (AFM) (trade name: SPA-400, manufactured by Seiko Instruments Inc.).

(Reduced Metal Particles)

The plating undercoat polymer layer according to the invention contains reduced metal particles. The reduced metal particle contained in the plating undercoat polymer layer is obtained by applying a metal precursor to the above-described plating undercoat polymer layer that has been formed on the support, and then reducing the metal precursor, thereby converting the metal precursor into a reduced metal particle. When a metal precursor is applied to the plating undercoat polymer layer, the metal precursor adheres to the interactive group due to interaction.

Hereinafter, the metal precursor contained in the plating undercoat polymer layer is described.

(Metal Precursor)

There is no particular limitation as to the metal precursor used in the invention, and any substance may be used as far as it has a function as an electrode when converted into a metal through a reduction reaction. Further, a substance that functions as an electrode for plating in the process of forming a silver-containing metal layer is preferable as the metal precursor. Therefore, the metal precursor is preferably a substance that functions as an electrode when reduced into a metal.

Specifically, an ion of a metal such as Au, Pt, Pd, Ag, Cu, Ni, Al, Fe, or Co is used. A metal ion that serves as a metal precursor is incorporated in the composition containing a plating undercoat polymer (composition for forming a plating undercoat polymer layer), and after forming a layer on the support, the metal ion is converted into a zero-valent metal particle through a reduction reaction.

The metal ion that serves as a metal precursor is preferably incorporated in the composition for forming a plating undercoat polymer layer in the form of a metal salt.

The metal salt to be used is not particularly limited as long as the metal salt dissolves in an appropriate solvent and dissociates into a metal ion and a base (anion). Examples of such a metal salt include M(NO₃)ₙ, MClₙ, M_{2/n}(SO₄), and M_{3/n}(PO₄) (M represents an n-valent metal atom). As the metal ion, a metal ion obtained by dissociation of any of the above metal salts can be used preferably. Examples include an Ag ion, a Cu ion, an Al ion, an Ni ion, a Co ion, an Fe ion, and a Pd ion. Above all, a metal ion capable of multidentate coordination is preferred, and particularly, an Ag ion, a Cu ion, and a Pd ion are preferable from the viewpoints of the type and number of the functional groups capable of coordination and catalytic capacity.

One of preferable examples of the metal precursor used in the invention is a silver ion.

In the case of using a silver ion, a silver ion obtained by dissociating a silver compound as shown below can be used preferably. Specific examples of the silver compound include silver nitrate, silver acetate, silver sulfate, silver carbonate, silver cyanide, silver thiocyanate, silver chloride, silver bromide, silver chromate, silver chloranilate, silver salicylate, silver diethyldithiocarbamate, silver diethyldithiocarbamidate, and silver p-toluenesulfonate. Among them, silver nitrate is preferable from the viewpoint of water solubility.

Further, another preferable example of the metal precursor is a copper ion. In the case of using a copper ion, a copper ion obtained by dissociating a copper compound as shown below can be used preferably. Specific examples of the copper compound include copper nitrate, copper acetate, copper sulfate, copper cyanide, copper thiocyanate, copper chloride, copper bromide, copper chromate, copper chloranilate, copper salicylate, copper diethyldithiocarbamate, copper diethyldithiocarbamidate, and copper p-toluenesulfonate. Among them, copper sulfate is preferable from the viewpoint of water solubility.

The metal precursor described above is preferably applied to the plating undercoat polymer layer in the form of a dispersion liquid or a solution (a metal precursor liquid).

An example of the application method is a method of forming a layer on the support, using the composition containing a plating undercoat polymer, and then bringing the layer into contact with a composition (a dispersion liquid or a metal precursor liquid) containing a metal precursor, by way of dipping or the like, thereby forming a plating undercoat polymer layer containing a metal precursor.

As the solvent used in the dispersion liquid of the metal precursor and the solvent used in the solution of the metal precursor, water or an organic solvent is used. By the inclusion of water or an organic solvent, the permeability of the metal precursor with respect to the polymer layer may be enhanced, and the metal precursor can be efficiently adsorbed to the interactive group.

In order to apply a metal precursor to the plating undercoat polymer layer, in the case of using a dispersion liquid of the metal precursor, the particle diameter of the metal precursor is preferably from 1 nm to 200 nm, more preferably from 1 nm to 100 nm, and still more preferably from 1 nm to 60 nm. By having such a particle diameter, the particle diameter of the reduced metal particle can be controlled to a desired size.

The term “particle diameter” used herein refers to an average primary particle diameter (in terms of volume), and the measurement method is the same as the method described below in the paragraph of metal particles.

It is preferable that the water used in the metal precursor liquid is free from impurities. From such a point of view, it is preferable to use RO water, deionized water, distilled water, purified water, or the like, and it is particularly preferable to use deionized water or distilled water. The organic solvent used in the metal precursor liquid is not particularly limited as long as the solvent is a solvent capable of permeating into the polymer layer. For example, acetone, methyl acetoacetate, ethyl acetoacetate, ethylene glycol diacetate, cyclohexanone, acetylacetone, acetophenone, 2-(1-cyclohexenyl)cyclolhexanone, propylene glycol diacetate, triacetine, diethylene glycol diacetate, dioxane, N-methylpyrrolidone, dimethyl carbonate, dimethyl cellosolve, or the like can be used.

Particularly, from the viewpoints of mutual solubility with the metal precursor and permeability into the polymer layer, water or a water-soluble organic solvent is preferable, and specifically, acetone, dimethyl carbonate, dimethyl cellosolve, triethylene glycol monomethyl ether, diethylene glycol dimethyl ether, and diethylene glycol diethyl ether are preferable.

Further, additional additives may be added to the dispersion liquid or solution, according to the purpose. Examples of the additional additives include a swelling agent and a surfactant.

The particle diameter of the reduced metal particles contained in the plating undercoat polymer layer is preferably from 1 nm to 200 nm, more preferably from 1 nm to 100 nm, and still more preferably from 1 nm to 60 nm. When the diameter is within this range, the reflectance after plating becomes favorable.

The term “particle diameter” used herein refers to an average primary particle diameter (in terms of volume), and is a value read from the SEM (trade name: S-5200, manufactured by Hitachi High-Tech Manufacturing & Service Corporation) image.

The surface resistance value of the plating undercoat polymer layer containing reduced metal particles is preferably from 0.001Ω/□ to 100Ω/□, and more preferably from 0.03Ω/□ to 50Ω/□. When the surface resistance value is within this range, a uniform and smooth plated surface may be formed, and a favorable reflectance may be achieved.

Regarding the method of measuring the surface resistance, measurement is carried out using a surface resistance meter (trade name: LORESTA-GP MCP-T600, manufactured by Mitsubishi Chemical Corporation).

<(C) Reflective Layer Containing Silver and Having a Surface Roughness Ra of 20 nm or Less>

The reflective layer containing silver (hereinafter, if appropriate, referred to as “silver-containing metal layer”) in the invention is a reflective layer that is constituted of a metal film containing silver, and the outermost surface, namely, the surface on the side on which the (D) resin protective layer described below is to be formed should have a surface roughness Ra of 20 nm or less. The reflective layer may be a single layer of a metal layer or may have a laminate structure of plural metal layers having different metal composition, but it is preferable that the outermost surface layer is a metal layer containing silver, since silver has excellent reflectivity.

The silver-containing metal layer according to the invention is obtained by forming a silver-containing metal film on the plating undercoat polymer layer containing reduced metal particles, by an electroplating method or the like.

As a method other than electroplating, methods such as vapor deposition, sputtering, or the like may be used.

The metal that forms the silver-containing metal layer according to the invention is silver or an alloy including silver, in terms of light reflection performance. Silver or an alloy including silver has a function of increasing the reflectance of the mirror film in the visible light region and can reduce the dependency of reflectance on the angle of incidence. The term “visible light region” means a wavelength region of from 400 nm to 700 nm. Here, the term “angle of incidence” means the angle with respect to a line perpendicular to the film surface.

From the viewpoints of the reflectance and durability, the silver alloy is preferably an alloy composed of silver and one or more kinds of metal selected from the group consisting of gold, palladium, tin, gallium, indium, copper, titanium, and bismuth, and particularly, an alloy of silver and gold is preferable.

The content of silver is preferably from 90 atom % to 100 atom % with respect to the total (100 atom %) of silver and other metal in the silver-containing metal layer, from the viewpoints of the reflectance and durability. Further, the content of the other metal is preferably from 0 atom % to 10 atom %.

The surface roughness (Ra) of the silver-containing metal layer in the invention is preferably 20 nm or less, more preferably 10 nm or less, and still more preferably 5 nm or less. When the surface roughness is within this range, the reflectance of the mirror film obtained may be increased, the heat and light of the sun may be efficiently concentrated, and the energy efficiency when used in a solar thermal power generator may be enhanced.

Hereinafter, the case of forming a silver-containing metal layer by an electroplating method is explained.

As to the electroplating method, a conventionally known method can be used.

In the invention, in a case in which the plating undercoat polymer layer containing reduced metal particles has a function as an electrode, electroplating may be performed with respect to the plating undercoat polymer layer, whereby a silver-containing metal layer can be formed.

A metal layer containing other metal, for example, copper, nickel, chrome, iron, or the like, can be provided as a ground metal layer between the plating undercoat polymer layer and the silver-containing metal layer.

Further, the film thickness of the silver-containing metal layer that is obtained by electroplating can be controlled by adjusting the concentration of the metal contained in the plating bath, the current density, or the like. When a ground metal layer having an appropriate thickness is provided, an increase in the reflectance due to surface smoothing and a decrease in the number of pinholes become possible.

From the viewpoint of forming a reflective film without a pinhole, and from the viewpoint of not making irregularities that allow light to scatter at the surface of the silver-containing metal layer, the film thickness of the silver-containing metal layer is preferably from 0.05 μm to 2.0 μm, and more preferably from 0.08 μm to 0.5 μm.

Alternatively, a silver-containing metal layer may be formed by performing dry plating such as vacuum vapor deposition or the like, utilizing the plating undercoat polymer layer that contains metal particles obtained by reducing a metal precursor. In this case, since the surface is covered with a metal, a silver-containing metal layer having favorable adhesion as compared with the case of ordinary vapor deposition or the like, and also having resistance to heat can be formed.

Further, after performing electroplating, the silver-containing metal layer may be treated with a strong acid, a strong alkali, or the like, in order to further enhance the reflection performance of the silver-containing metal layer, or to enhance the durability of the silver-containing metal layer. Alternatively, an inorganic coat or a metal oxide coat may be formed on the metal surface. Moreover, a discoloration preventing agent layer may be provided by treating with a discoloration preventing agent.

The discoloration preventing agent layer functions so as to prevent discoloration of the silver-containing metal layer. Examples of the discoloration preventing agent include thio ether type, thiol type, Ni-based organic compound type, benzotriazole type, imidazole type, oxazole type, tetrazaindene type, pyrimidine type, and thiazole type.

In the discoloration preventing agent layer, when classified roughly, a substance having an adsorptive group for silver and an antioxidant are preferably used. Hereinafter, specific examples of these agents are described.

(Discoloration Preventing Agent Having Adsorptive Group for Silver)

The discoloration preventing agent having an adsorptive group for silver is preferably at least one kind or a mixture of two or more kinds selected from the group consisting of amines and derivatives thereof, compounds having a pyrrole ring, compounds having a triazole ring, compounds having a pyrazole ring, compounds having a thiazole ring, compounds having an imidazole ring, compounds having an indazole ring, copper chelate compounds, thioureas, compounds having a mercapto group, and naphthalene-based compounds.

Examples of the amines and derivatives thereof include ethylamine, lauryl amine, tri-n-butylamine, o-toluidine, diphenylamine, ethylenediamine, diethylenetriamine, triethylenetetramine, tetraethylenepentamine, monoethanolamine, diethanolamine, triethanolamine, N,N-dimethylethanolamine, 2-amino-2-methyl-1,3-propanediol, acetamide, acrylamide, benzamide, p-ethoxychrysoidine, dicyclohexyl ammonium nitrite, dicyclohexyl ammonium salicylate, monoethanolamine benzoate, dicyclohexyl ammonium benzoate, diisopropyl ammonium benzoate, diisopropyl ammonium nitrite, cyclohexylamine carbamate, nitronaphthalene ammonium nitrite, cyclohexylamine benzoate, dicyclohexyl ammonium cyclohexane carboxylate, cyclohexylamine cyclohexane carboxylate, dicyclohexyl ammonium acrylate, cyclohexylamine acrylate, and the like, and any mixture thereof.

Examples of the compounds having a pyrrole ring include N-butyl-2,5-dimethylpyrrole, N-phenyl-2,5-dimethylpyrrole, N-phenyl-3-formyl-2,5-dimethylpyrrole, N-phenyl-3,4-diformyl-2,5-dimethylpyrrole, and the like, and any mixture thereof.

Examples of the compounds having a triazole ring include 1,2,3-triazole, 1,2,4-triazole, 3-mercapto-1,2,4-triazole, 3-hydroxy-1,2,4-triazole, 3-methyl-1,2,4-triazole, 1-methyl-1,2,4-triazole, 1-methyl-3-mercapto-1,2,4-triazole, 4-methyl-1,2,3-triazole, benzotriazole, tolyltriazole, 1-hydroxybenzotriazole, 4,5,6,7-tetrahydrotriazole, 3-amino-1,2,4-triazole, 3-amino-5-methyl-1,2,4-triazole, carboxybenzotriazole, 2-(2′-hydroxy-5′-methylphenyl)benzotriazole, 2-(2′-hydroxy-5′-tert-butylphenyl)benzotriazole, 2-(2′-hydroxy-3′,5′-di-tert-butylphenyl)benzotriazole, 2-(2′-hydroxy-4-octoxyphenyl)benzotriazole, and the like, and any mixture thereof.

Examples of the compounds having a pyrazole ring include pyrazole, pyrazoline, pyrazolone, pyrazolidine, pyrazolidone, 3,5-dimethylpyrazole, 3-methyl-5-hydroxypyrazole, 4-aminopyrazole, and the like, and any mixture thereof.

Examples of the compounds having a thiazole ring include thiazole, thiazoline, thiazolone, thiazolidine, thiazolidone, isothiazole, benzothiazole, 2-(N,N-diethylthio)benzothiazole, p-dimethylaminobenzalrhodanine, 2-mercaptobenzothiazole, and the like, and any mixture thereof.

Examples of the compounds having an imidazole ring include imidazole, histidine, 2-heptadecylimidazole, 2-methylimidazole, 2-ethyl-4-methylimidazole, 2-phenylimidazole, 2-undecylimidazole, 1-benzyl-2-methylimidazole, 2-phenyl-4-methylimidazole, 1-cyanoethyl-2-methylimidazole, 1-cyanoethyl-2-phenylimidazole, 1-cyanoethyl-2-ethyl-4-methylimidazole, 1-cyanoethyl-2-undecylimidazole, 2-phenyl-4-methyl-5-hydroxymethylimidazole, 2-phenyl-4,5-dihydroxymethylimidazole, 4-formylimidazole, 2-methyl-4-formylimidazole, 2-phenyl-4-formylimidazole, 4-phenyl-5-formylimidazole, 2-ethyl-4-methyl-5-formylimidazole, 2-phenyl-4-methyl-4-formylimidazole, 2-mercaptobenzimidazole, and the like, and any mixture thereof.

Examples of the compounds having an indazole ring include 4-chloroindazole, 4-nitroindazole, 5-nitroindazole, 4-chloro-5-nitroindazole, and the like, and any mixture thereof.

Examples of the copper chelate compounds include copper acetylacetone, copper ethylenediamine, copper phthalocyanine, copper ethylenediamine tetraacetate, copper hydroxyquinoline, and the like, and any mixture thereof.

Examples of thioureas include thiourea, guanylthiourea, and the like, and any mixture thereof.

Examples of the compounds having a mercapto group include, when the materials described above are included, mercaptoacetic acid, thiophenol, 1,2-ethanedithiol, 3-mercapto-1,2,4-triazole, 1-methyl-3-mercapto-1,2,4-triazole, 2-mercaptobenzothiazole, 2-mercaptobenzimidazole, glycol dimercapto acetate, 3-mercaptopropyltrimethoxysilane, and the like, and any mixture thereof.

Examples of naphthalene-based compounds include thionalide and the like.

<(D) Resin Protective Layer>

The mirror film of the invention has (D) a resin protective layer on the light incident side, for the purpose of preventing deterioration in light resistance due to sunlight or ultraviolet rays.

As the resin protective layer, films obtained by dispersing an ultraviolet absorbent in various kinds of conventionally known resins, a UV curable resin having an ultraviolet absorbent dispersed therein, or a thermosetting resin having an ultraviolet absorbent dispersed therein can be used.

Examples of the resin film used in the resin film having an ultraviolet absorbent dispersed therein may include a cellulose ester-based film, a polycarbonate-based film, a polyarylate-based film, a polysulfone (including polyethersulfone) based film, a polyester-based film of polyethylene terephthalate, polyethylene naphthalate, or the like, a polyethylene film, a polypropylene film, cellophane, a cellulose diacetate film, a cellulose triacetate film, a cellulose acetate propionate film, a cellulose acetate butyrate film, a polyvinylidene chloride film, a polyvinyl alcohol film, an ethylene vinyl alcohol film, a cyndiotactic polystyrene-based film, a polycarbonate film, a norbornene-based resin film, a polymethylpentene film, a polyether ketone film, a polyether ketone imide film, a polyamide film, a fluorine resin film, a nylon film, and an acrylic film (an acrylic film containing polymethyl methacrylate as the main component, or the like). Among them, a polycarbonate-based film, a polyester-based film, a norbornene-based resin film, a cellulose ester-based film, and an acrylic film are preferable.

Particularly, an acrylic film is more preferable from the viewpoint of light transmittance. It is particularly preferable to use an acrylic film containing polymethyl methacrylate as the main component. Further, either of a film produced by melt casting film formation or a film produced by solution casting film formation may be used.

Further, it is preferable that the film used for the resin protective layer contains an ultraviolet absorbent, and as the ultraviolet absorbent, those described above can be used.

The content of the ultraviolet absorbent in the resin protective layer is from 0.1% by mass to 20% by mass, preferably from 1% by mass to 15% by mass, and more preferably from 3% by mass to 10% by mass, with respect to the total mass of the resin protective layer. When the content is higher than 20% by mass, the adhesion is deteriorated, and when the content is lower than 0.1% by mass, the effects on the improvement of weather resistance is small.

It is preferable that the (D) resin protective layer is adhered onto the (C) silver-containing metal layer via an adhesion layer. The adhesion layer is required to have adhesion such that the silver-containing metal layer closely adheres to the resin protective layer, weather resistance, and smoothness to bring about high reflection performance, and not to have absorption of light in the reflected light region.

A resin is used in the adhesion layer, and the resin used is not particularly limited as long as the resin satisfies the requirements including the above-described adhesion, weather resistance, heat resistance, smoothness, and the like, and a polyurethane-based resin, a polyester-based resin, an acryl-based resin, a melamine-based resin, an epoxy-based resin, a polyamide-based resin, a vinyl chloride-based resin, a vinyl chloride/vinyl acetate copolymer-based resin, or the like may be used singly, or a mixed resin thereof may be used. From the viewpoint of weather resistance, a mixed resin of a polyester-based resin and a melamine-based resin or a polyurethane-based resin is preferable, and a thermosetting type in which a curing agent such as isocyanate is further mixed is more preferable. Further, the adhesion layer may include the ultraviolet absorbent described above, a plasticizer for maintaining flexibility, an antioxidant that prevents deterioration of the film itself, a radical scavenger, or the like.

The thickness of the adhesion layer is preferably from 0.01 μm to 15 μm, and more preferably from 0.1 μm to 5 μm. When the thickness is less than 0.01 μm, the adhesion is deteriorated, so that the effect of forming an adhesion layer is not exhibited, and further, it is difficult to cover the fine irregularities of the film base material surface to make the surface smooth, resulting in deterioration in the smoothness, which is thus not preferable. Even when the thickness is more than 5 μm, improvement of adhesion cannot be expected, and rather, the smoothness may be deteriorated due to the occurrence of coating unevenness, or curing of the adhesion layer may be insufficient, which is thus not preferable.

As the method of forming the adhesion layer, a conventionally known coating method such as a gravure coat method, a reverse coat method, or a die coat method is applicable.

The mirror film of the invention has the above configuration. It is preferable that the mirror film of the invention has a reflectance of 90% or higher, and more preferably 94% or higher, with respect to light having a wavelength of 600 nm.

The reflectance is measured using a spectrophotometer (trade name: UV-3100PC, manufactured by Shimadzu Corporation), and the value at a wavelength of 600 nm is used.

For concentrating sunlight, the mirror film may be bonded to a unit having rigidity. The term “unit having rigidity” refers to a metal such as SUS, Al, or an Al alloy, a resin such as polyvinyl chloride, polycarbonate, or acryl, or a composite material such as CRP or FRP. The mirror film can be bonded to a unit having a shape to concentrate light, via the following sticky layer.

The sticky layer is not particularly limited and, for example, any of a dry laminating agent, a wet laminating agent, a heat sealing agent, a hot melt agent, or the like may be used. For example, a polyester-based resin, a urethane-based resin, a polyvinyl acetate-based resin, an acryl-based resin, a nitrile rubber, a silicone resin, or the like is used. The lamination method is not particularly limited, and it is preferable that lamination is successively carried out, for example, by a roll system, in terms of economic efficiency and productivity. The thickness of the sticky layer is usually selected from the range of about 1 μm to about 50 μm. When the thickness is less than 1 μm, a sufficient adhesion effect cannot be obtained, whereas when the thickness exceeds 50 μm, the sticky layer is too thick, such that the drying rate is slow, resulting in being inefficient. In addition, the original adhesive force cannot be obtained, and disadvantages such that solvents remain and the like may be caused, which is thus not preferable.

Further, the resins described in the above adhesion layer may also be used in the sticky layer.

The thickness of the whole mirror film according to the invention is preferably from 75 μm to 250 μm, more preferably from 90 μm to 230 μm, and still more preferably from 100 μm to 220 μm. When the thickness is less than 75 μm, the mirror film may bend at the time of bonding the mirror film to a unit such as a metal or the like, so that a sufficient reflectance cannot be obtained, and when the thickness is more than 250 nm, the handling property may be deteriorated, which is thus not preferable.

The resin protective layer, that is the outermost layer of the mirror film obtained as described above, preferably has a surface roughness of 20 nm or less, and more preferably 10 nm or less. By the surface roughness being within this range, a mirror film having a high reflectance can be produced.

<Method for Producing Mirror Film>

Next, with regard to the method for producing the mirror film of the invention, each process is explained sequentially. The method described below is one embodiment of the invention, and the invention is not limited thereto.

The method for producing a mirror film of the invention is characterized in that the method includes a process of forming a plating undercoat polymer layer containing reduced metal particles on a support (which is referred to as “process 1”.), a process of forming a metal layer containing silver by electroplating (which is referred to as “process 2”.), and a process of forming a resin protective layer (which is referred to as “process 3”.).

[Process of Forming a Plating Undercoat Polymer Layer Containing Reduced Metal Particles on a Support]

It is preferable that the process of forming a plating undercoat polymer layer containing reduced particles on a support includes a process of forming a polymer layer containing a metal precursor (which is referred to as “process 1-1”.), and a process of reducing the metal precursor (which is referred to as “process 1-2”.).

Further, it is preferable that the “process 1-1” includes a process of providing a layer on a support by way of coating or the like, using a composition for forming a polymer layer, the composition containing a plating undercoat polymer, and then applying energy to form a polymer layer (“process 1-1-1”), and a process of applying a metal precursor to the polymer layer (“process 1-1-2”).

Note that, the “composition for forming a polymer layer, the composition containing a plating undercoat polymer” means a composition that does not contain a metal precursor, but contains a plating undercoat polymer and other components such as a solvent. Further, the “polymer layer” means a layer that does not contain a metal precursor, but contains a plating undercoat polymer and other components, and is formed on a support.

(Process 1-1-1)

In the process 1-1-1, by applying energy to the support having a polymer layer, the polymerizable group contained in the plating undercoat polymer and the functional group at the surface of the support are activated, and a crosslink between the polymers, a chemical bond between the support and the polymer layer, and the like are formed. As a result, the polymer layer and the support tightly adhere to each other.

The method of providing the polymer layer on the support is not particularly limited, and the method described above in regard to “the method of forming a plating undercoat polymer layer” can be applied without change.

As for the amount of the composition for forming a polymer layer applied onto the support, the composition containing the plating undercoat polymer, the application amount described above as “the application amount in the case of contacting the composition for forming a plating undercoat polymer layer with the support” can be applied without change.

In the process 1-1-1, in forming the polymer layer, exposure may be carried out in a state in which the solvent after coating remains, or exposure may be carried out after drying to remove the residual solvent, but from the viewpoint of surface smoothness of the polymer layer, it is preferable that exposure is carried out after drying. As the drying condition, the drying condition described above as “the drying condition in forming the plating undercoat polymer layer” can be applied without change.

The energy application method in the process 1-1-1 may use, for example, heating or exposure.

As the light source, in the case of carrying out exposure, the light source described above as the light source used in the “application of energy” can be applied without change. Further, also with regard to the energy application method, the energy application method described above can be applied without change.

In the case of carrying out heating, for example, a generally used heating roller, a laminator, a hot stamp, an electric heating plate, a thermal head, a laser, an air blow dryer, an oven, a hot plate, an infrared dryer, a heating drum, or the like can be used.

The time needed for energy application may vary with the light source, but the time is usually in a range of from 0.5 seconds to 5 hours.

Further, the above energy application methods may be used in combination. For example, exposure and heating may be used in combination.

In a case in which application of energy is carried out by exposure, the exposure power is preferably in a range of from 10 mJ/cm² to 8,000 mJ/cm², and more preferably in a range of from 100 mJ/cm² to 3,000 mJ/cm², for the purpose of facilitating the progress of polymerization, suppressing the decomposition of polymer, and obtaining smoother surface after the removal of unreacted polymer as described below.

Further, in a case in which application of energy is carried out by heating, the temperature is preferably in a range of from 20° C. to 200° C., and more preferably in a range of from 40° C. to 120° C., for the purpose of facilitating the progress of polymerization and suppressing the thermal denaturation of support.

Further, exposure may be carried out in an atmosphere in which the oxygen concentration is suppressed to 600 ppm or less, preferably 400 ppm or less, by carrying out substitution with inert gas such as nitrogen, helium, or carbon dioxide. Moreover, if necessary, application of energy may be carried out in a patterned manner.

After the energy application, if appropriate, the unreacted plating undercoat polymer may be removed from the polymer layer that has been subjected to energy application. An example of the removal method is a method using a solvent. For example, the method described above in regard to “the removal of the unreacted plating undercoat polymer” can be applied without change.

The thickness of the polymer layer obtained is not particularly limited, but from the viewpoint of adhesion of the silver-containing metal layer to the support, the thickness is preferably from 0.05 μm to 10 μm, and more preferably from 0.3 μm to 5 μm.

Further, the dry weight is preferably from 0.05 g/m² to 10 g/m², and particularly preferably from 0.3 g/m² to 5 g/m².

Moreover, the surface roughness (Ra) of the polymer layer is preferably 20 nm or less, and more preferably 10 nm or less, in terms of reflection performance.

The content of the polymer in the polymer layer is preferably in a range of from 2% by mass to 100% by mass, and more preferably in a range of from 10% by mass to 100% by mass, with respect to the total amount of the polymer layer.

(Process 1-1-2)

The method of applying a metal precursor to the polymer layer obtained in the process 1-1-1 is not particularly limited.

Examples of the method include a method of preparing a dispersion liquid, which is obtained by dispersing a metal precursor in a proper dispersion medium, or a solution, which is obtained by dissolving a metal salt in a proper solvent and contains a dissociated metal ion, and then coating the dispersion liquid or the solution (metal precursor liquid) on the polymer layer; and a method of dipping the substrate formed thereon the polymer layer into the dispersion liquid or the solution.

The time for contacting the polymer layer with the metal precursor-containing liquid (dispersion liquid or solution) is preferably from about 30 seconds to about 24 hours, and more preferably from about 1 minute to about 1 hour.

The temperature of the metal precursor-containing liquid at the time of contact is preferably from about 5° C. to about 80° C., and more preferably from about 15° C. to about 60° C.

When the metal precursor-containing liquid is brought into contact with the polymer layer as described above, the metal precursor can be adsorbed to the interactive group in the plating undercoat polymer, by utilizing an interaction caused by an intermolecular force such as van der Waal's force, or an interaction caused by a coordinate bond due to lone electron pair.

From the viewpoint of sufficiently carrying out such adsorption, the concentration of the metal precursor or the concentration of the metal ion in the metal precursor-containing liquid is preferably in a range of from 0.001% by mass to 50% by mass, and more preferably in a range of from 0.005% by mass to 30% by mass.

(Process 1-2: Process of Reducing Metal Precursor)

The metal ion, as the metal precursor, applied to the polymer layer is reduced using a metal activating liquid (a reducing liquid). The metal activating liquid includes a reducing agent capable of reducing a metal precursor (mainly, a metal ion) to a zero-valent metal, and a pH adjusting agent for activating the reducing agent.

The concentration of the reducing agent with respect to the whole metal activating liquid is preferably from 0.05% by mass to 50% by mass, and more preferably from 0.1% by mass to 30% by mass.

As the reducing agent, it is possible to use a boron-based reducing agent such as sodium borohydride or dimethylamine borane, or a reducing agent such as formaldehyde or phosphinic acid.

Particularly, it is preferable to perform reduction using an aqueous alkali solution containing formaldehyde.

The concentration of the pH adjusting agent with respect to the whole metal activating liquid is preferably in a range of from 0.05% by mass to 10% by mass, and more preferably in a range of from 0.1% by mass to 5% by mass.

As the pH adjusting agent, it is possible to use acetic acid, hydrochloric acid, sulfuric acid, nitric acid, sodium hydrogencarbonate, aqueous ammonia, sodium hydroxide, potassium hydroxide, or the like.

Further, the temperature at the time of reduction is preferably from 10° C. to 100° C., and more preferably from 20° C. to 70° C.

It is preferable that these concentration and temperature ranges are the above ranges, from the viewpoints of the particle diameter of the metal precursor, the surface roughness and electric conductivity (surface resistance value) of the polymer layer, and deterioration of the reducing liquid, at the time of reduction.

In the succeeding process of forming a silver-containing metal layer, with regard to the surface resistance value of the plating undercoat polymer layer containing reduced metal particles, Ra of the surface of the plating undercoat polymer layer containing reduced metal particles, and the particle diameter of the reduced metal particles, the values described above may be applied without change.

(Process 2: Process of Forming Metal Layer Containing Silver)

A metal layer containing silver is formed on the plating undercoat polymer layer containing reduced metal particles by an electroplating method or the like. As the electroplating method, a conventionally known method can be used.

In the invention, in a case in which the plating undercoat polymer layer containing reduced metal particles has a function as an electrode, a silver-containing metal layer can be formed by performing electroplating with respect to the plating undercoat polymer layer containing reduced metal particles.

Examples of a silver compound which may be used for plating include silver nitrate, silver acetate, silver sulfate, silver carbonate, silver methanesulfonate, ammoniated silver, silver cyanide, silver thiocyanate, silver chloride, silver bromide, silver chromate, silver chloranilate, silver salicylate, silver diethyldithiocarbamate, silver diethyldithiocarbamidate, and silver p-toluenesulfonate. Among them, silver methanesulfonate is preferable, from the viewpoints of the effect on environment and smoothness.

(Process 3: Process of Forming Resin Protective Layer)

The silver-containing metal layer is bonded together with a protective film that forms the resin protective layer.

An example of the bonding method is a method of coating the above-described adhesive agent on the protective film or on the silver-containing metal face and bonding the protective film and the silver-containing metal layer.

Further, the resin protective layer may be formed, for example, by a method of welding the protective film by way of thermal lamination or the like; a method of melting the material for forming the protective film and casting the melt on the silver-containing metal layer to form a resin protective layer; a method of coating the material for forming the protective film on the silver-containing metal layer and then allowing to carry out a reaction of some kind, to form a resin protective film; or a method of forming a resin protective layer by way of vacuum deposition or the like. In the case of using the above method, the protective layer can be formed directly on the silver-containing metal layer, without providing an adhesion layer therebetween.

The mirror film thus obtained is bonded to a unit having rigidity or the like, by using the above-described tackifier or the like, and the resulting assembly is integrated, as the material for concentrating the light or heat of sunlight or the like, into a solar thermal power generator or a solar photovoltaic power generator.

Since the mirror film of the invention has the above configuration, the mirror film is produced by a simple method, has favorable adhesion between the support and the reflective layer made of a metal, is lightweight, and has excellent light reflection efficiency.

### EXAMPLES

Hereinafter, the present invention is specifically described with reference to Examples. However, the present invention is by no means limited to these Examples. Unless stated otherwise, the “%” and “parts” are based on mass.

### Example 1

### Process of Forming Plating Undercoat Polymer Layer

To a solution containing 7% by mass of acrylic polymer 1 (the following structure, the numbers attached to the repeating units represent the composition ratio, in terms of mass), 74% by mass of 1-methoxy-2-propanol, and 19% by mass of water, 0.35% by mass of a photopolymerization initiator ESACURE KTO-46 (trade name, manufactured by Lamberti SpA) were added, and the mixture was stirred, thereby preparing a plating undercoat polymer (acrylic polymer 1) solution.

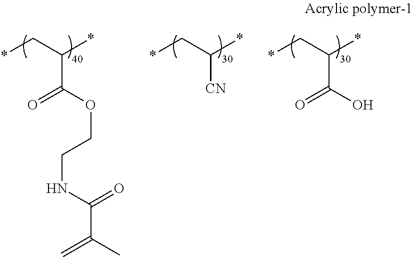

The plating undercoat polymer solution thus obtained was coated on a polyethylene terephthalate (PET) film COSMOSHINE A4300 (trade name, manufactured by Toyobo Co., Ltd.) such that the film thickness after drying was about 0.55 μm, by a bar coat method, followed by drying at 25° C. for 10 minutes and at 80° C. for 5 minutes. Thereafter, using a UV irradiation device (manufactured by GS Uasa Corporation; UV lamp: a metal halide lamp), UV exposure was performed in a manner such that the exposure amount at a wavelength of 254 nm was 1,000 mJ/cm².

The obtained PET film having a plating undercoat polymer coated thereon was immersed in a 1% by mass aqueous solution of sodium hydrogencarbonate for 5 minutes, followed by washing with pure running water for 1 minute, to remove the unreacted polymer.

(Application of Metal Precursor)

As the solution containing a metal precursor, a 1% by mass aqueous solution of silver nitrate was prepared. The PET film substrate having a plating undercoat polymer coated thereon, the PET film substrate having been obtained in the above process, was immersed in the prepared metal precursor solution at 25° C. for 5 minutes, followed by washing with pure running water for 1 minute, to carry out application of metal precursor.

(Reduction of Metal Precursor)

As the reducing liquid, an aqueous solution containing 0.25% by mass of formaldehyde and 0.14% by mass of sodium hydroxide was prepared. The PET film substrate having a metal precursor applied thereto, the PET film substrate having been obtained in the above process, was immersed in the prepared reducing liquid at 25° C. for 1 minute, followed by washing with pure running water for 1 minute, to carry out reduction of metal precursor.

The surface resistance value after the reduction, which was measured by using a surface resistance meter, was about 10Ω/□. Further, Ra measured by using an AFM was about 7 nm. The average primary particle diameter of the metal after the reduction, which was measured by using an SEM, was about 50 nm.

(Electroplating)

As a pretreatment of electroplating, the PET film substrate having, on its surface, a plating undercoat polymer layer containing reduced metal particles, the PET film substrate having been obtained in the above process, was immersed in a 10% by mass aqueous solution of DAN CLEANER AC 100 (trade name, manufactured by Daiwa Fine Chemical Co., Ltd.) at 25° C. for 30 seconds, followed by washing for several times. Subsequently, also as a pretreatment of electroplating, the resulting PET film substrate was immersed in a 10% by mass aqueous solution of DAN SILVER ACC (trade name, manufactured by Daiwa Fine Chemical Co., Ltd.) for 10 seconds, followed by washing for several times.

As the electroplating liquid, DAN SILVER BRIGHT PL50 (trade name, manufactured by Daiwa Fine Chemical Co., Ltd.; main component: silver methanesulfonate) was used, and the pH was adjusted to 9.0 with 8 M potassium hydroxide. The above PET film substrate having, on its surface, a plating undercoat polymer layer containing reduced metal particles was immersed in the electroplating liquid, to thereby carry out plating at 0.5 A/dm² for 20 seconds.

As a post treatment of electroplating, the PET film substrate after plating was immersed in a 10% by mass aqueous solution of DAN SILVER ACC (trade name, manufactured by Daiwa Fine Chemical Co., Ltd.; main component: methanesulfonic acid) for 90 seconds, followed by washing for several times.

Ra after the post treatment of plating was measured using an AFM, and found to be about 4 nm.

(Formation of Protective Layer)

41.8% by mass of LIS-825 (trade name, manufactured by TOYO INK CO., LTD.) and 3% by mass of LCR-901 (trade name, manufactured by TOYO INK CO., LTD.), as adhesive agents, were dissolved in 55.2% by mass of ethyl acetate, to prepare an adhesive agent solution.

The adhesive agent solution thus obtained was coated on the silver plated face obtained in the above process such that the film thickness after drying was about 10 μm, by a bar coat method, followed by drying at room temperature for 2 minutes and at 80° C. for 10 minutes.

This assembly was bonded to a UV absorbent-containing PMMA film, S001G (trade name, manufactured by Sumitomo Chemical Co., Ltd.), as a protective layer, using a laminator (at a lamination speed of 0.1 m/min, and a lamination pressure of 0.5 MPa). Thereafter, post-heating was carried out at 60° C. for 12 hours, thereby curing the adhesive agents.

With regard to the silver face after bonding with the protective layer, the reflectance at 600 nm was measured and found to be about 94%.

(Performance Evaluation)

Using the mirror film obtained as described above, the following evaluation was performed. The results are shown in Table 3 together with the results of other Examples and Comparative Examples.

<1. Surface Roughness (Ra)>

Measurement was carried out using an atomic force microscope (AFM), SPA-400 (trade name, manufactured by Seiko Instruments Inc.).

The surface roughness of the reduced metal was measured using a sample after reduction of the metal precursor, and the surface roughness of the plated metal was measured using a sample after electroplating.

<2. Surface Resistance Value>

Measurement was carried out using a surface resistance meter LORESTA-GP MCP-T600 (trade name, manufactured by Mitsubishi Chemical Corporation).

<3. Particle Diameter of Reduced Metal Particles>

The average primary particle diameter of the reduced metal particles was read from the SEM (trade name: S-5200, manufactured by Hitachi High-Tech Manufacturing & Service Corporation) image.

<4. Reflectance>

The reflectance was measured using a spectrophotometer (trade name: UV-3100PC, manufactured by Shimadzu Corporation).

<5. Adhesion>

The adhesion test was carried out as follows in accordance with the tape test method described in JIS H8504. On the mirror film, equally spaced cuts were made in a grid using a utility knife, to form 100 squares of 2 mm×2 mm, and thereafter, a peeling test was carried out using a piece of tape, and evaluation was performed according to the following criteria.

A: No peeling

B: Peeling occurs, and less than 25% of the squares are peeled off

C: 25% or more but less than 50% of the squares are peeled off

D: 50% or more of the squares are peeled off

<6. Weather Resistance>

In the weather resistance test, using a thermohygrostat PR-3ST (trade name, manufactured by ESPEC CORP.), the mirror film was left for 1,000 hours under an environment of a temperature of 65° C. and a humidity of 80% RH, and was evaluated according to the following criteria.

A: The reflectance at 600 nm is decreased by 0% or more but less than 3%, as compared with the reflectance before the test.

B: The reflectance at 600 nm is decreased by 3% or more but less than 10%, as compared with the reflectance before the test.

C: The reflectance at 600 nm is decreased by 10% or more but less than 50%, as compared with the reflectance before the test.

### Example 2

On the reduced silver before conducting electrolytic silver plating in Example 1, electroplating was carried out under the conditions of 3 A/dm² for 45 seconds using a copper plating bath having the composition described below, and thereafter, electroplating was further carried out under the conditions of 4 A/dm² for 72 seconds using a nickel plating bath having the composition described below. Thereafter, electrolytic silver plating and formation of protective layer were carried out in a manner similar to that in Example 1. The reflectance at 600 nm was about 95%, and the surface roughness (Ra) of the silver-containing metal layer was 3.5 nm.

The mirror film thus obtained was evaluated in a manner similar to that in Example 1.

(Composition of Electrolytic Copper Plating Bath)

| | | |
|---|---|---|
| Copper sulfate | 38 | g |
| Sulfuric acid | 95 | g |
| Hydrochloric acid | 1 | mL |
| COPPER GLEAM PCM (trade name, manufactured | 3 | mL |
| by Meltex Inc.) | | |
| Water | 500 | g |

(Composition of Electrolytic Nickel Plating Bath; 1 L Composition)

| | | |
|---|---|---|
| Nickel sulfate | 100 | g |
| Nickel chloride | 15 | g |
| Boric acid | 45 | g |
| BR220 MAKEUP (trade name, manufactured by Rohm & | 10 | mL |
| Haas Electronic Materials K.K.) | | |
| BR220 CARRIER (trade name, manufactured by Rohm & | 35 | mL |
| Haas Electronic Materials K.K.) | | |
| BR220 REPLENISHER (trade name, manufactured by | 2 | mL |
| Rohm & Haas Electronic Materials K.K.) | | |
| NAW-A (trade name, manufactured by Rohm & Haas | 3 | mL |
| Electronic Materials K.K.) | | |

| | |
|---|---|
| Water | residue |

### Example 3

Production of a mirror film was conducted in a manner similar to that in Example 1, except that the exposure amount in the exposure of the plating undercoat polymer layer was changed to 90 mJ/cm². The mirror film thus obtained was evaluated in a manner similar to that in Example 1.

The surface resistance value after the reduction was 30Ω/□. The surface roughness (Ra) was 15 nm, the particle diameter of the reduced metal was about 70 nm, and the reflectance at 600 nm was about 90%. Further, the surface roughness (Ra) of the silver-containing metal layer was 10 nm.

### Comparative Example 1

After the silver nitrate in Example 1 was adsorbed to the polymer layer, using the silver that had been adsorbed as a catalyst, electroless plating was carried out for 20 minutes using an electroless copper plating bath having the composition described below. Then, electroplating was carried out for 10 minutes using an electrolytic copper plating bath having the composition described below. Thereafter, electrolytic silver plating and formation of protective layer were carried out in a manner similar to that in Example 1.

The mirror film thus obtained was evaluated in a manner similar to that in Example 1. The reflectance, at 600 nm, of the silver face after bonding with the protective layer was measured and found to be about 85%. The surface roughness Ra of the silver-containing metal layer was 25 nm.

(Composition of Electroless Copper Plating Bath; 1 L Composition)

| | | |
|---|---|---|
| Distilled water | 774 | g |
| ATS ADDCOPPER IW-A (trade name, manufactured by | 45 | mL |
| Okuno Chemical Industries Co., Ltd.) | | |
| ATS ADDCOPPER IW-M (trade name, manufactured by | 72 | mL |
| Okuno Chemical Industries Co., Ltd.) | | |
| ATS ADDCOPPER IW-C (trade name, manufactured by | 9 | mL |
| Okuno Chemical Industries Co., Ltd.) | | |
| NaOH | 1.98 | g |
| 2,2′-Bipyridyl | 1.8 | mg |
| (Composition of Electrolytic Copper Plating Bath) | | |
| Copper sulfate | 38 | g |
| Sulfuric acid | 95 | g |
| Hydrochloric acid | 1 | mL |
| COPPER GLEAM PCM (trade name, manufactured by | 3 | mL |
| Meltex Inc.) | | |
| Water | 500 | g |

### Comparative Example 2

Production of a mirror film was conducted in a manner similar to that in Example 1, except that the metal precursor that had been adsorbed was not reduced. The surface resistance value after the adsorption was 10⁷Ω/□ or more, and thus, it was impossible to carry out the succeeding plating.

### Comparative Example 3

Production of a mirror film was conducted in a manner similar to that in Example 1, except that the metal precursor was not adsorbed. The surface resistance value after the reduction was 10⁷Ω/□ or more, and thus, it was impossible to carry out the succeeding plating.

### Comparative Example 4

Production of a mirror film was conducted in a manner similar to that in Example 1, except that the plating undercoat polymer layer was not coated. The surface resistance value after the reduction was 10⁷Ω/□ or more, and thus, it was impossible to carry out the succeeding plating.

TABLE 3

| | Surface Roughness Ra | Surface | Particle Diameter of | Surface Roughness Ra | | | |
|---|---|---|---|---|---|---|---|
| | of Reduced Metal | Resistance | Reduced Metal Particles | of Plated Metal | Reflectance | | Weather |
| | [nm] | [Ω/□] | [nm] | [nm] | [%] | Adhesion | Resistance |
| Example1 | 7 | 10 | 50 | 4 | 94 | A | A |
| Example2 | 7 | 10 | 50 | 3.5 | 95 | A | A |
| Example3 | 15 | 30 | 70 | 10 | 90 | B | A |
| Comparative | — | 2 | — | 25 | 84 | C | B |
| Example 1 | | | | | | | |
| Comparative | — | 10⁷ | — | unable | — | — | — |
| Example2 | | or more | | plating | | | |
| Comparative | — | 10⁷ | — | unable | — | — | — |
| Example3 | | or more | | plating | | | |
| Comparative | — | 10⁷ | — | unable | — | — | — |
| Example4 | | or more | | plating | | | |

Further, with regard to the mirror films of Examples 1 to 3, the following evaluation was performed.

<7. Weather Resistance (2)>

Using a thermohygrostat (trade name: PR-3ST, manufactured by ESPEC CORP.), the mirror films of Examples 1 to 3 were left for 1,000 hours under an environment of a temperature of 70° C. and a humidity of 85% RH. As a result, the rates of change of reflectance at 600 nm were all within a range of 0% or more but less than 3%, as compared with the reflectance before the test.

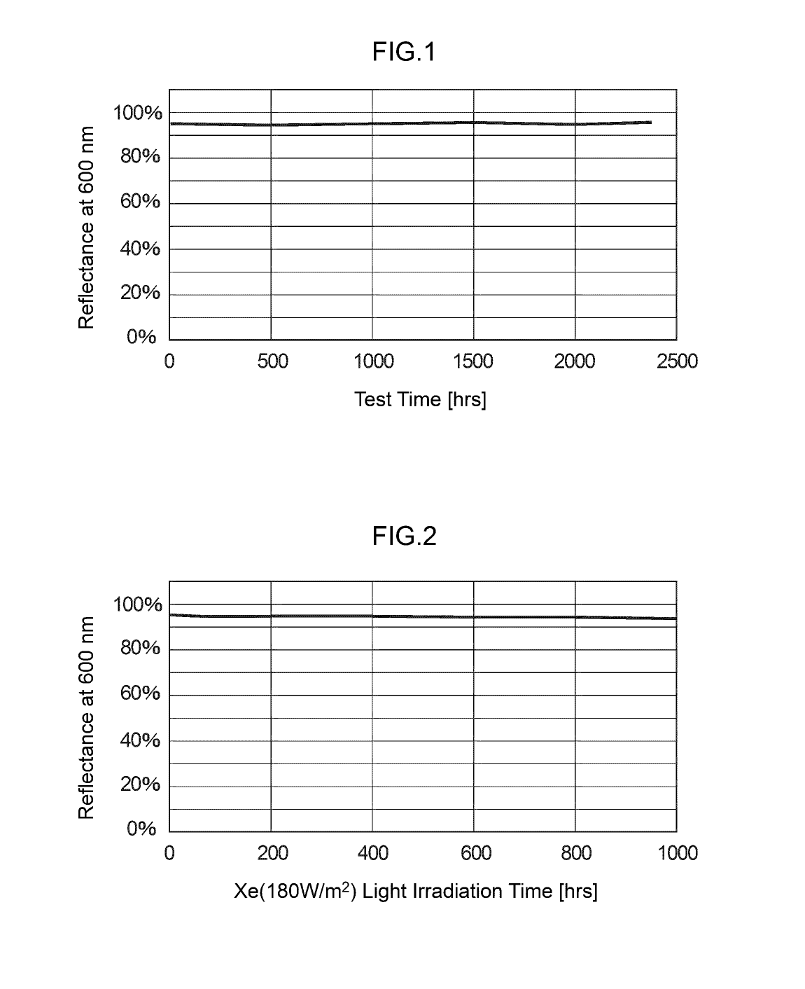

The results of the weather resistance (2) test of Example 1 are shown in FIG. 1.

<8. Light Resistance>

Further, using a XENON WEATHER-O METER (CI-5000, trade name, manufactured by Atlas Co., Ltd.), the mirror films of Examples 1 to 3 were left for 1,000 hours under an environment of Xe light irradiation with 180 W/m². As a result, the rates of change of reflectance at 600 nm were all within a range of 0% or more but less than 3%, as compared with the reflectance before the test.

The results of the light resistance test of Example 1 are shown in FIG. 2.

### Examples 4 to 11

Solutions of a plating undercoat polymer of Examples 4 to 11 were prepared by changing the acrylic polymer 1 in Example 1 to acrylic polymer 2 to 9 having the following structure, respectively, and mirror films were prepared in a manner similar to that in Example 1. Each of the mirror films thus obtained was evaluated in a manner similar to that in Example 1. The evaluation results are shown in Table 4.

Note that, the composition ratios in the following acrylic polymers 2 to 9 are shown on the basis of mass.

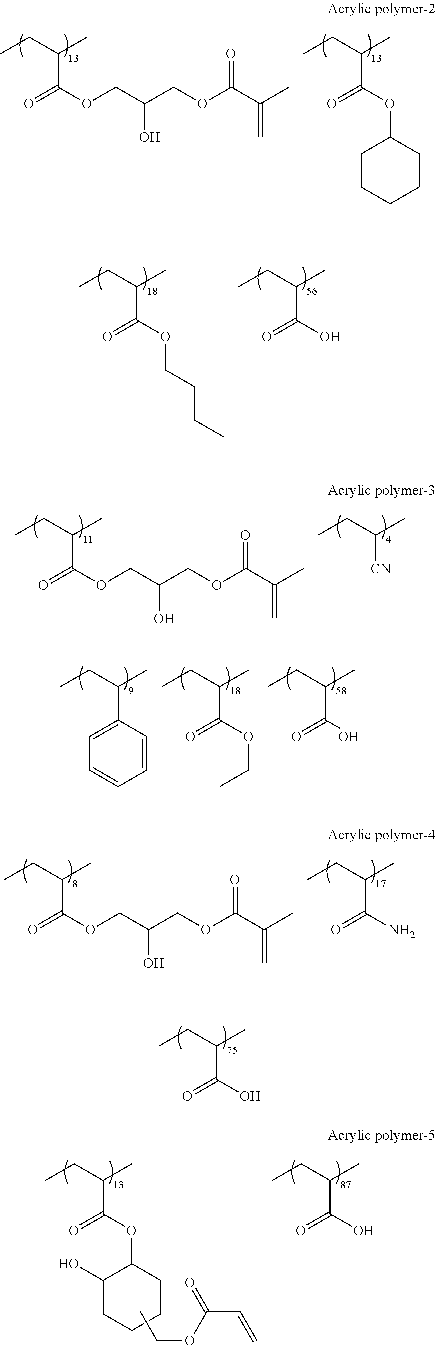

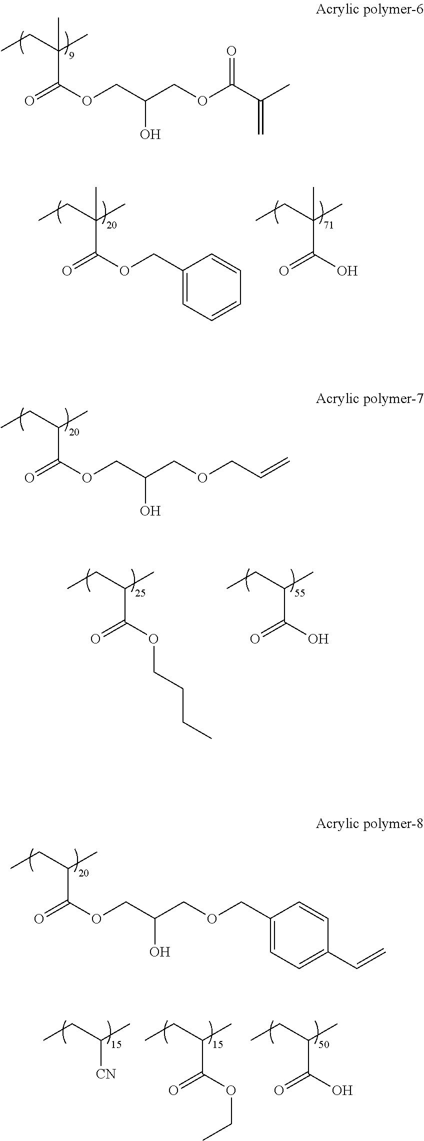

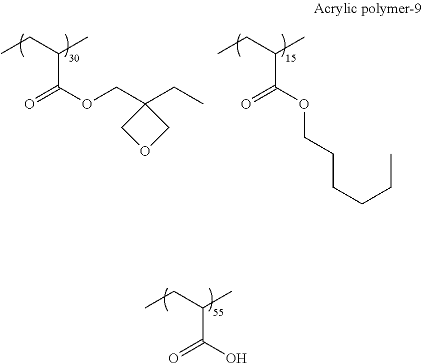

Synthesis of the acrylic polymers 2 to 9 was carried out as follows.

### Synthesis Example 1

### Synthesis of Acrylic Polymer 2

In a 2,000 mL three-necked flask, 309 g of 1-methoxy-2-propanol were placed and heated to 70° C. under a stream of nitrogen. Then, 277 g of acrylic acid, 111 g of cyclohexyl acrylate, 127 g of butyl acrylate, and a solution containing 15 g of V-601 (trade name, manufactured by Wako Pure Chemical Industries, Ltd.) and 471 g of 1-methoxy-2-propanol were added thereto dropwise over 4 hours. Thereafter, the resulting mixture was allowed to further react for 4 hours. Subsequently, 1.8 g of 2,6-di-tert-butyl-4-toluol, 1.8 g of tetrabutylammonium bromide (catalyst), and 105 g of glycidyl methacrylate were added to the reaction liquid, and the mixture was allowed to react at 100° C. After the completion of the reaction, 47 g of 1-methoxy-2-propanol were added to dilute the resulting liquid, thereby preparing a 1-methoxy-2-propanol solution of acrylic polymer 2, having a solid content of 40% by mass. The weight average molecular weight of the obtained acrylic polymer 2 was 2.0×10⁴, and the acid value was 5.2 meq/g.

### Synthesis Example 2

### Synthesis of Acrylic Polymer 3

In a 2,000 mL three-necked flask, 143 g of 1-methoxy-2-propanol were placed and heated to 70° C. under a stream of nitrogen. Then, 149 g of acrylic acid, 7.2 g of acrylonitrile, 14.2 g of styrene, 68.2 g of ethyl acrylate, and a solution containing 7.2 g of V-501 (trade name, manufactured by Wako Pure Chemical Industries, Ltd.) and 219 g of 1-methoxy-2-propanol were added thereto dropwise over 4 hours. Thereafter, the resulting mixture was allowed to further react for 4 hours. Subsequently, 1 g of 2,6-di-tert-butyl-4-toluol, 1 g of tetrabutylammonium bromide (catalyst), and 49 g of glycidyl methacrylate were added to the reaction liquid, and the mixture was allowed to react at 100° C. After the completion of the reaction, 22 g of 1-methoxy-2-propanol were added to dilute the resulting liquid, thereby preparing a 1-methoxy-2-propanol solution of acrylic polymer 3, having a solid content of 40% by mass. The weight average molecular weight of the obtained acrylic polymer 3 was 1.4×10⁴, and the acid value was 6.1 meq/g.

### Synthesis Example 3

### Synthesis of Acrylic Polymer 4

In a 2,000 mL three-necked flask, 216 g of 1-methoxy-2-propanol were placed and heated to 90° C. under a stream of nitrogen. Then, 319 g of acrylic acid, 11 g of acrylamide, and a solution containing 11 g of V-601 (trade name, manufactured by Wako Pure Chemical Industries, Ltd.) and 366 g of 1-methoxy-2-propanol were added thereto dropwise over 4 hours. The resulting mixture was allowed to react for 2 hours. Then, a solution containing 5 g of V-601 and 36 g of 1-methoxy-2-propanol were added thereto dropwise over 1 hour, and the resulting mixture was allowed to further react for 2 hours. Subsequently, 1.3 g of 2,6-di-tert-butyl-4-toluol, 1.3 g of tetrabutylammonium bromide (catalyst), and 74 g of glycidyl methacrylate were added to the reaction liquid, and the mixture was allowed to react at 100° C. After the completion of the reaction, 33 g of 1-methoxy-2-propanol were added to dilute the resulting liquid, thereby preparing a 1-methoxy-2-propanol solution of acrylic polymer 4, having a solid content of 40% by mass. The weight average molecular weight of the obtained acrylic polymer 4 was 3.8×10⁴, and the acid value was 9.0 meq/g.

### Synthesis Example 4

### Synthesis of Acrylic Polymer 5

In a 2,000 mL three-necked flask, 309 g of 1-methoxy-2-propanol were placed and heated to 100° C. under a stream of nitrogen. Then, 514 g of acrylic acid and a solution containing 15 g of V-601 (trade name, manufactured by Wako Pure Chemical Industries, Ltd.) and 501 g of 1-methoxy-2-propanol were added thereto dropwise over 8 hours. The resulting mixture was allowed to react for 2 hours. Then, a solution containing 7 g of V-601 and 80 g of 1-methoxy-2-propanol were added thereto dropwise over 1 hour, and the resulting mixture was allowed to further react for 2 hours. Subsequently, 2 g of 2,6-di-tert-butyl-4-toluol, 2 g of tetrabutylammonium hydroxide (catalyst), and 199 g of CYCLOMER A200 (trade name, manufactured by Daicel Corporation (former: Daicel Chemical Industries, Ltd.)) were added to the reaction liquid, and the mixture was allowed to react at 100° C. After the completion of the reaction, 61 g of 1-methoxy-2-propanol were added to dilute the resulting liquid, thereby preparing a 1-methoxy-2-propanol solution of acrylic polymer 5, having a solid content of 40% by mass. The weight average molecular weight of the obtained acrylic polymer 5 was 1.9×10⁴, and the acid value was 9.1 meq/g.

### Synthesis Example 5

### Synthesis of Acrylic Polymer 6

In a 1,000 mL three-necked flask, 126 g of 1-methoxy-2-propanol were placed and heated to 100° C. under a stream of nitrogen. Then, 136 g of methacrylic acid, 73 g of benzyl methacrylate, and a solution containing 4.2 g of V-601 (trade name, manufactured by Wako Pure Chemical Industries, Ltd.) and 201 g of 1-methoxy-2-propanol were added thereto dropwise over 3 hours. The resulting mixture was allowed to react for 2 hours. Then, a solution containing 3 g of V-601 and 42 g of 1-methoxy-2-propanol were added thereto dropwise over 1 hour, and the resulting mixture was allowed to further react for 2 hours. Subsequently, 0.8 g of 2,6-di-tert-butyl-4-toluol, 0.8 g of tetrabutylammonium iodide (catalyst), and 52.2 g of glycidyl methacrylate were added to the reaction liquid, and the mixture was allowed to react at 100° C. After the completion of the reaction, 24 g of 1-methoxy-2-propanol were added to dilute the resulting liquid, thereby preparing a 1-methoxy-2-propanol solution of acrylic polymer 6, having a solid content of 40% by mass. The weight average molecular weight of the obtained acrylic polymer 6 was 3.7×10⁴, and the acid value was 6.1 meq/g.

### Synthesis Example 6

### Synthesis of Acrylic Polymer 7

In a 2,000 mL three-necked flask, 256 g of 1-methoxy-2-propanol were placed and heated to 100° C. under a stream of nitrogen. Then, 296 g of acrylic acid, 160 g of butyl acrylate, and a solution containing 10 g of V-601 (trade name, manufactured by Wako Pure Chemical Industries, Ltd.) and 151 g of 1-methoxy-2-propanol were added thereto dropwise over 7 hours. The resulting mixture was allowed to react for 2 hours. Then, a solution containing 3 g of V-601 and 49 g of 1-methoxy-2-propanol were added thereto dropwise over 1 hour, and the resulting mixture was allowed to further react for 2 hours.

Subsequently, 1 g of 2,6-di-tert-butyl-4-toluol, 2 g of tetrabutylammonium bromide (catalyst), and 114 g of allyl glycidyl ether were added to the reaction liquid, and the mixture was allowed to react at 100° C. After the completion of the reaction, 271 g of 1-methoxy-2-propanol were added to dilute the resulting liquid, thereby preparing a 1-methoxy-2-propanol solution of acrylic polymer 7, having a solid content of 40% by mass. The weight average molecular weight of the obtained acrylic polymer 7 was 2.9×10⁴, and the acid value was 5.0 meq/g.

### Synthesis Example 7

### Synthesis of Acrylic Polymer 8

In a 2,000 mL three-necked flask, 350 g of 1-methoxy-2-propanol were placed and heated to 70° C. under a stream of nitrogen. Then, 252 g of acrylic acid, 75 g of ethyl acrylate, 40 g of acrylonitrile, and a solution containing 12 g of V-501 (trade name, manufactured by Wako Pure Chemical Industries, Ltd.) and 156 g of 1-methoxy-2-propanol were added thereto dropwise over 7 hours. The resulting mixture was allowed to react for 2 hours. Then, a solution containing 3 g of V-501 and 45 g of 1-methoxy-2-propanol were added thereto dropwise over 1 hour, and the resulting mixture was allowed to further react for 2 hours.

Subsequently, 1 g of 2,6-di-tert-butyl-4-toluol, 2 g of tetrabutylammonium bromide (catalyst), and 190 g of vinylbenzyl glycidyl ether were added to the reaction liquid, and the mixture was allowed to react at 100° C. After the completion of the reaction, 285 g of 1-methoxy-2-propanol were added to dilute the resulting liquid, thereby preparing a 1-methoxy-2-propanol solution of acrylic polymer 8, having a solid content of 40% by mass. The weight average molecular weight of the obtained acrylic polymer 8 was 2.1×10⁴, and the acid value was 4.6 meq/g.

### Synthesis Example 8

### Synthesis of Acrylic Polymer 9

In a 2,000 mL three-necked flask, 400 g of 1-methoxy-2-propanol were placed and heated to 100° C. under a stream of nitrogen. Then, 198 g of acrylic acid, 117 g of hexyl acrylate, 255 g of 3-ethyl-3-oxetanyl methyl methacrylate, and a solution containing 13 g of V-601 (trade name, manufactured by Wako Pure Chemical Industries, Ltd.) and 306 g of 1-methoxy-2-propanol were added thereto dropwise over 7 hours. The resulting mixture was allowed to react for 2 hours. Then, a solution containing 3 g of V-501 and 50 g of 1-methoxy-2-propanol were added thereto dropwise over 1 hour, and the resulting mixture was allowed to further react for 2 hours. After the completion of the reaction, 100 g of 1-methoxy-2-propanol were added, thereby preparing a 1-methoxy-2-propanol solution of acrylic polymer 9, having a solid content of 40% by mass. The weight average molecular weight of the obtained acrylic polymer 9 was 1.8×10⁴, and the acid value was 4.9 meq/g.

The reaction time in Synthesis Examples 1 to 8, and the acid values and weight average molecular weights of the respective acrylic polymers were measured as follows.

<Reaction Time>

Using gas chromatography, the time at which the residual amount of glycidyl methacrylate became 1% or less was determined, which was designated as the reaction time.

Measurement Conditions in Gas Chromatography

### Column: DB-5 (1: 30 m, Φ: 0.53 mm, d: 1.5 μm)

Injection temperature: 250° C.
Detection temperature: 250° C.
Column temperature: 100° C., retaining the temperature for 5 minutes, then elevating the temperature with a temperature elevating rate of 10° C./min until the temperature reaches 280° C., then retaining the temperature for 10 minutes
Sample injection quantity: 4 μL

<Acid Value>

Measurement was conducted by titration using an aqueous solution of sodium hydroxide, and a value with respect to the solids amount of the acrylic polymer was determined.

<Weight Average Molecular Weight>

Measurement was conducted by gel permeation chromatography (GPC) using polystyrene as a standard reference material.

The acid values and weight average molecular weights of the respective acrylic polymers are shown in Table 4.

TABLE 4

| | Acid Value | Weight Average |
|---|---|---|
| | (meq/g) | Molecular Weight |
| Acrylic polymer-1 | 4.4 | 38,000 |
| Acrylic polymer-2 | 5.2 | 20,000 |
| Acrylic polymer-3 | 6.1 | 14,000 |
| Acrylic polymer-4 | 9.0 | 38,000 |
| Acrylic polymer-5 | 9.1 | 19,000 |
| Acrylic polymer-6 | 6.1 | 37,000 |
| Acrylic polymer-7 | 5.0 | 29,000 |
| Acrylic polymer-8 | 4.6 | 21,000 |
| Acrylic polymer-9 | 4.9 | 18,000 |

The chemical names of the catalysts in Synthesis Examples 1 to 8 are as follows.

V-501: (trade name, manufactured by Wako Pure Chemical Industries, Ltd.) dimethyl 2,2′-azobis(2-methylpropionate)

V-601: (trade name, manufactured by Wako Pure Chemical Industries, Ltd.) 4,4′-azobis(4-cyanovaleric acid)

TABLE 5

| | | Surface | | | | | | |
|---|---|---|---|---|---|---|---|---|
| | | Roughness Ra | | Particle Diameter | | | | |
| | Plating | of Reduced | Surface | of Reduced Metal | Surface Roughness | | | |
| | Undercoat | Metal | Resistance | Particles | Ra of Plated Metal | Reflectance | | Weather |
| | Polymer | [nm] | [Ω/□] | [nm] | [nm] | [%] | Adhesion | Resistance |
| Example 4 | Acrylic | 8 | 10 | 60 | 4.2 | 94 | A | A |
| | polymer-2 | | | | | | | |
| Example 5 | Acrylic | 8 | 10 | 50 | 5.0 | 95 | A | A |
| | polymer-3 | | | | | | | |
| Example 6 | Acrylic | 10 | 10 | 70 | 20 | 90 | A | A |
| | polymer-4 | | | | | | | |
| Example 7 | Acrylic | 10 | 10 | 50 | 10 | 93 | A | A |
| | polymer-5 | | | | | | | |
| Example 8 | Acrylic | 10 | 10 | 100 | 5.0 | 85 | B | A |
| | polymer-6 | | | | | | | |
| Example 9 | Acrylic | 10 | 10 | 70 | 8.0 | 90 | B | A |
| | polymer-7 | | | | | | | |
| Example 10 | Acrylic | 10 | 10 | 80 | 10 | 91 | B | A |
| | polymer-8 | | | | | | | |
| Example 11 | Acrylic | 14 | 10 | 100 | 20 | 83 | B | A |
| | polymer-9 | | | | | | | |

In the weather resistance (2) test, after leaving the mirror films of Examples 4 to 11 under an environment of a temperature of 70° C. and a humidity of 85% RH for 1,000 hours, the rates of change of reflectance at 600 nm were all within the range of 0% or more but less than 3%, as compared with the reflectance before the test.

Further, after leaving the mirror films of Examples 4 to 11 under an environment of Xe light irradiation with 180 W/m² for 1,000 hours, using a lightfastness tester (trade name: CI 5000 XENON WEATHER-O METER, manufactured by Atlas Co., Ltd.), the rates of change of reflectance at 600 nm were all within the range of 0% or more but less than 3%, as compared with the reflectance before the test.

From the above results, it is evident that the mirror films of the invention have high reflectivity, high adhesion, and high weather resistance.

The disclosures of Japanese Patent Application No. 2012-029957 filed on Feb. 14, 2012 and Japanese Patent Application No. 2012-218261 filed on Sep. 28, 2012 are incorporated by reference herein in their entirety.

All publications, patent applications, and technical standards mentioned in this specification are herein incorporated by reference to the same extent as if such individual publication, patent application, or technical standard was specifically and individually indicated to be incorporated by reference.

What is claimed is:

1. A mirror film, comprising, in this order:
a support;
a plating undercoat polymer layer containing reduced metal particles;
a reflective layer containing silver; and
a resin protective layer,
a surface roughness Ra of a surface of the reflective layer containing silver at a resin protective layer side being 20 nm or less.

2. The mirror film according to claim 1, wherein an average primary particle diameter of the reduced metal particles is in a range of from 1 nm to 100 nm.

3. The mirror film according to claim 1, wherein a surface roughness Ra of a surface of the plating undercoat polymer layer containing the reduced metal particles at a reflective layer side is 20 nm or less.

4. The mirror film according to claim 3, wherein a surface resistance value of the plating undercoat polymer layer containing the reduced metal particles is in a range of from 0.001Ω/□ to 100Ω/□.

5. The mirror film according to claim 3, wherein the surface resistance value of the plating undercoat polymer layer containing the reduced metal particles is in a range of from 0.03Ω/□ to 50 Ω/□.

6. The mirror film according to claim 1, wherein the plating undercoat polymer layer containing the reduced metal particles comprises an acrylic polymer.

7. The mirror film according to claim 6, wherein the acrylic polymer is an acrylic polymer having an acidic group and a polymerizable group in a side chain thereof, and forms an interaction between polymerizable groups of the acrylic polymer, or between the polymerizable groups of the acrylic polymer and the support, by applying energy, within the plating undercoat polymer layer.

8. The mirror film according to claim 1, having a light reflectance of 90% or higher at a wavelength of 600 nm.

9. A method of producing the mirror film according to claim 1, comprising:
forming a plating undercoat polymer layer containing reduced metal particles on a support;
forming a reflective layer containing silver, by electroplating; and
forming a resin protective layer.

10. The method of producing the mirror film according to claim 9, wherein the forming of a plating undercoat polymer layer containing reduced metal particles comprises:
forming a polymer layer containing a metal precursor on the support; and
reducing the metal precursor.

11. The method of producing the mirror film according to claim 10, wherein the forming of a polymer layer containing a metal precursor on the support comprises applying the metal precursor after imparting energy to the support having a polymer layer.

12. The method of producing the mirror film according to claim 9, wherein the polymer used to form the undercoat polymer layer is selected from the group consisting of:
a copolymer comprising:
a structural unit containing a polymerizable group and represented by the following Formula (A),
a structural unit containing a first interactive group and represented by the following Formula (B), the first interactive group being a non-dissociative functional group, and
a structural unit containing a second interactive group and represented by the following Formula (C), the second interactive group being an ionic polar group;
a copolymer comprising:
the structural unit represented by the following Formula (A), and
the structural unit represented by the following Formula (B); and
a copolymer comprising:
the structural unit represented by the following Formula (A), and
the structural unit represented by the following Formula (C): 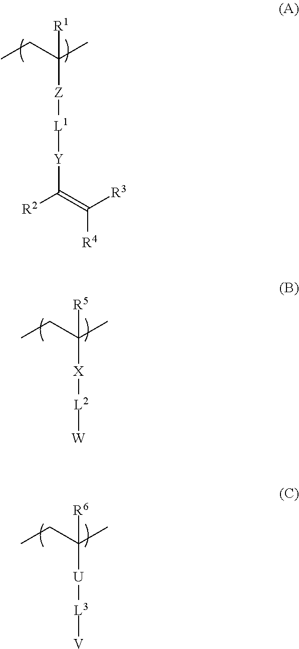
wherein, in Formulae (A) to (C), each of R1 to R6 independently represents a hydrogen atom or a substituted or unsubstituted alkyl group having from 1 to 4 carbon atoms; each of X, Y, Z, and U independently represents a single bond, a substituted or unsubstituted divalent organic group, an ester group, an amide group, or an ether group; each of L¹, L², and L³ independently represents a single bond, or a substituted or unsubstituted divalent organic group; W represents a non-dissociative functional group that forms an interaction with a plating catalyst or a precursor thereof; and V represents an ionic polar group that forms an interaction with a plating catalyst or a precursor thereof.

13. The method of producing the mirror film according to claim 10, wherein forming a plating undercoat polymer layer containing reduced metal particles on the support comprises applying, on the support, a composition for forming a polymer layer, the composition comprising a material that generates an active species.

14. The method of producing the mirror film according to claim 11, comprising:
removing unreacted polymer after the application of energy to the support having the undercoat polymer layer; and
thereafter, reducing the metal precursor.

15. The production method of the mirror film according to claim 10, wherein reducing the metal precursor comprises reducing a metal precursor by contacting the metal precursor with an aqueous solution containing a reducing agent.

16. The production method of the mirror film according to claim 9, wherein forming a reflective layer containing silver, by electroplating, comprises washing the support having the undercoat polymer layer after the electroplating.

17. A solar thermal power generator or a solar photovoltaic power generator comprising the mirror film according to claim 1.

18. The mirror film according to claim 5, having a light reflectance of 90% or higher at a wavelength of 600 nm, wherein an average primary particle diameter of the reduced metal particles is in a range of from 1 nm to 100 nm.

19. The mirror film according to claim 18, wherein the plating undercoat polymer layer containing the reduced metal particles comprises an acrylic polymer, and the acrylic polymer is an acrylic polymer having an acidic group and a polymerizable group in a side chain thereof, and forms an interaction between polymerizable groups of the acrylic polymer, or between the polymerizable groups of the acrylic polymer and the support, by applying energy, within the plating undercoat polymer layer.

20. The method of producing the mirror film according to claim 12, wherein the forming of a plating undercoat polymer layer containing reduced metal particles comprises:
forming a polymer layer containing a metal precursor on the support; and
reducing the metal precursor, and the forming of a polymer layer containing a metal precursor comprises:
applying the metal precursor after imparting energy to the support having a polymer layer.

21. The production method of the mirror film according to claim 20, wherein reducing the metal precursor comprises reducing a metal precursor by contacting the metal precursor with an aqueous solution containing a reducing agent, and forming a reflective layer containing silver, by electroplating, comprises washing the support having the undercoat polymer layer after the electroplating.

22. A solar thermal power generator or a solar photovoltaic power generator comprising the mirror film according to claim 21.
